(19) United States
(12) Patent Application Publication
(10) Pub. No.: US 2024/0147773 A1
(43) Pub. Date: May 2, 2024

(54) DISPLAY DEVICE AND ELECTRONIC DEVICE INCLUDING THE SAME

(71) Applicant: Samsung Display Co., Ltd., Yongin-si (KR)

(72) Inventors: JUNG-YUN KIM, Yongin-si (KR); DEOKHOI KIM, Yongin-si (KR); SUNGIN RO, Yongin-si (KR)

(21) Appl. No.: 18/464,948

(22) Filed: Sep. 11, 2023

(30) Foreign Application Priority Data
Oct. 27, 2022 (KR) 10-2022-0140701

(51) Int. Cl. H10K 59/122; H10K 59/126

(52) U.S. Cl. CPC H10K 59/122; H10K 59/126

(57) ABSTRACT

A display device includes a base layer having a plurality of pixel regions and a non-pixel region surrounding the plurality of pixel regions, a circuit layer including a plurality of insulating layers and a plurality of conductive patterns, a light-emitting element layer, and an input sensing unit including a sensing pattern overlapping the non-pixel region. The light-emitting element layer includes a pixel defining structure overlapping the non-pixel region, and a plurality of light-emitting elements. The pixel defining structure includes a step pattern surrounding a portion of each of the plurality of pixel regions. The plurality of conductive patterns include a shielding pattern on the plurality of insulating layers and overlapping at the step pattern in a plan view, at least a portion of the shielding pattern being applied with voltage.

### CROSS-REFERENCE TO RELATED APPLICATIONS

The present application claims priority to and the benefit of Korean Patent Application No. 10-2022-0140701, filed on Oct. 27, 2022, the entire content of which is incorporated herein by reference.

### BACKGROUND

Aspects of some embodiments of the present disclosure herein relate to a display device and an electronic device including the same.

Electronic devices for displaying images to users, such as smartphones, tablet PCs, digital cameras, laptop computers, navigation devices, and TVs, may include a display a display device for displaying images.

To display a color image in a display device, pixels may be separately formed as red, green, and blue pixels, and an emission layer of color of a corresponding pixel may be formed in each corresponding pixel. In general, a deposition method using a shadow mask may be used to form an emission layer. However, because a fault such as mask sag may occur, a process for commonly forming an emission layer and other organic layers over all pixels through an open mask has been developed.

However, when commonly forming an organic layer, lateral leakage current may occur due to the organic layer commonly provided between adjacent pixels, causing the occurrence of color mixing between adjacent pixels or luminance deterioration.

The above information disclosed in this Background section is only for enhancement of understanding of the background and therefore the information discussed in this Background section does not necessarily constitute prior art.

### SUMMARY

Aspects of some embodiments of the present disclosure herein relate to a display device and an electronic device including the same, and for example, to a display device with improved reliability and an electronic device including the same.

Aspects of some embodiments of the present disclosure include a display device that may be capable of preventing or reducing color mixing between adjacent pixels, deterioration of luminance, and deterioration of sensitivity of an input sensing unit and an electronic device including the same.

A display device according to some embodiments of the present disclosure includes a base layer, in which a plurality of pixel regions including a first pixel region and a second pixel region adjacent to the first pixel region and a non-pixel region surrounding the plurality of pixel regions are defined, a circuit layer arranged on the base layer and including a plurality of insulating layers and a plurality of conductive patterns, a light-emitting element layer arranged on the circuit layer, and an input sensing unit arranged on the light-emitting element layer and including a sensing pattern overlapping the non-pixel region. According to some embodiments, the light-emitting element layer includes a pixel defining structure, which overlaps the non-pixel region and in which a plurality of pixel openings corresponding to the plurality of pixel regions respectively are defined, and a plurality of light-emitting elements arranged at least partially in the plurality of pixel openings. According to some embodiments, the pixel defining structure includes a step pattern overlapping the non-pixel region and surrounding a portion of each of the plurality of pixel regions. According to some embodiments, the plurality of conductive patterns include a shielding pattern arranged on at least one of the plurality of insulating layers and overlapping at least a portion of the step pattern in a plan view, at least a portion of the shielding pattern being applied with voltage.

According to some embodiments, the light-emitting element may include a first electrode arranged on the circuit layer, an organic layer arranged on the first electrode and the pixel defining structure and including an emission layer, and a second electrode arranged on the organic layer, wherein a portion of the organic layer and the second electrode may be arranged on the step pattern.

According to some embodiments, the pixel defining structure may further include a pixel defining layer overlapping the non-pixel region, the step pattern may have a shape recessed from an upper surface of the pixel defining layer in a thickness direction of the pixel defining layer, and the step pattern may include a lower surface that is parallel with the upper surface of the pixel defining layer, and an inner side surface connecting the lower surface and the upper surface of the pixel defining layer.

According to some embodiments, the organic layer may include a first portion arranged on the upper surface of the pixel defining layer, and a second portion arranged on the inner side surface of the step pattern, wherein a thickness of the second portion may be smaller than a thickness of the first portion.

According to some embodiments, the second electrode may include a first electrode portion arranged on the upper surface of the pixel defining layer, and a second electrode portion arranged on the inner side surface of the step pattern, wherein a thickness of the second electrode portion may be smaller than a thickness of the first electrode portion.

According to some embodiments, the pixel defining structure may further include a dummy portion arranged on the pixel defining layer and partially overlapping the step pattern in a plan view, and the organic layer may include a third portion arranged on the dummy portion, and a fourth portion arranged on the lower surface of the step pattern, wherein the third portion and the fourth portion may not be connected.

According to some embodiments, the pixel defining structure may further include a pixel defining layer overlapping the non-pixel region, and the step pattern may include a side surface arranged on the pixel defining layer and having an inversely tapered shape from an upper surface of the pixel defining layer.

According to some embodiments, the organic layer may include a fifth portion arranged on the pixel defining layer, and a sixth portion arranged on the step pattern, wherein the fifth portion and the sixth portion may not be connected.

According to some embodiments, the first electrode may be applied with a first power supply voltage, and the shielding pattern may be applied with a second power supply voltage different from the first power supply voltage.

According to some embodiments, the organic layer may include a first light-emitting stack arranged on the first electrode and the pixel defining layer and including a first emission layer, a first charge generation layer arranged on the first light-emitting stack, and a second light-emitting stack arranged between the first charge generation layer and the second electrode and including a second emission layer.

According to some embodiments, the step pattern may include a first step pattern surrounding a portion of the first pixel region, and a second step pattern surrounding a portion of the second pixel region, wherein when a portion in which the first step pattern does not surround the first pixel region is defined as a first open portion, and a portion in which the second step pattern does not surround the second pixel region is defined as a second open portion, the first open portion and the second open portion may not face each other.

According to some embodiments, the shielding pattern may overlap each of the first open portion and the second open portion of the step pattern in a plan view.

According to some embodiments, the shielding pattern may include a first shielding pattern overlapping the first step pattern in a plan view, and a second shielding pattern overlapping the second step pattern in a plan view, wherein a first sub open portion corresponding to the first open portion may be defined in the first shielding pattern, and a second sub open portion corresponding to the second open portion may be defined in the second shielding pattern.

According to some embodiments, the circuit layer further include a dummy shielding pattern arranged in the same layer as the shielding pattern, spaced apart from the shielding pattern, and surrounding any one of the plurality of pixel regions.

According to some embodiments, the shielding pattern may overlap the first step pattern and may not overlap the second step pattern in a plan view.

According to some embodiments, the circuit layer may further include a signal line electrically connected to the light-emitting element, and the plurality of insulating layers may include a first base insulating layer in which the signal line is arranged, and a second base insulating layer, which is arranged on the first base insulating layer and in which the shielding pattern is arranged.

According to some embodiments, the circuit layer may further include a signal line electrically connected to the light-emitting element, and the signal line and the shielding pattern may be arranged on the same layer among the plurality of insulating layers.

According to some embodiments, the plurality of pixel regions may further include a third pixel region adjacent to the second pixel region, the first pixel region may display first light, the second pixel region may display second light of a wavelength different from that of the first light, and the third pixel region may display third light of a wavelength different from those of the first light and the second light.

According to some embodiments, the circuit layer may further include an active voltage line overlapping a portion of the plurality of pixel regions in a plan view, and the shielding pattern may be electrically connected to the active voltage line through a shielding contact hole defined in at least one of the plurality of insulating layers.

According to some embodiments, a first region having a first unit area size and a second region having a second unit area size that is the same as the first unit area size and spaced apart from the first region may be defined in the base layer, and the number of the shielding contact holes defined in the first region and the number of the shielding contact holes defined in the second region may be different from each other.

According to some embodiments, the sensing pattern may overlap at least a portion of the shielding pattern in a plan view.

A display device according to some embodiments of the present disclosure includes a base layer, in which a plurality of pixel regions including a first pixel region and a second pixel region adjacent to the first pixel region and a non-pixel region surrounding the plurality of pixel regions are defined, a plurality of insulating layers arranged on the base layer, a shielding pattern arranged on the plurality of insulating layers and overlapping the non-pixel region, at least a portion of the shielding pattern being applied with voltage, a pixel defining structure, which overlaps the non-pixel region and in which a plurality of pixel openings corresponding to the plurality of pixel regions respectively are defined, and a light-emitting element arranged on the plurality of insulating layers and including an organic layer and an upper electrode arranged on the organic layer, wherein the pixel defining structure includes a step pattern overlapping the non-pixel region and surrounding a portion of each of the plurality of pixel regions, a portion of the organic layer and the upper electrode is arranged on the step pattern, and the step pattern overlaps at least a portion of the shielding pattern in a plan view.

An electronic device according to some embodiments of the present disclosure includes a display module, in which a plurality of pixel regions including a first pixel region and a second pixel region adjacent to the first pixel region and displaying light of a wavelength different from that of the first pixel region and a non-pixel region surrounding the plurality of pixel regions are defined, a window arranged on the display module, and an external case arranged under the display module. According to some embodiments, the display module includes a base layer, in which a plurality of pixel regions including a first pixel region and a second pixel region adjacent to the first pixel region and a non-pixel region surrounding the plurality of pixel regions are defined, a circuit layer arranged on the base layer and including a plurality of insulating layers and a plurality of conductive patterns, a light-emitting element layer arranged on the circuit layer, and an input sensing unit arranged on the light-emitting element layer and including a sensing pattern overlapping the non-pixel region.

According to some embodiments, the light-emitting element layer includes a pixel defining structure, which overlaps the non-pixel region and in which a plurality of pixel openings corresponding to the plurality of pixel regions respectively are defined, and a plurality of light-emitting elements arranged at least partially in the plurality of pixel openings. According to some embodiments, the pixel defining structure includes a step pattern overlapping the non-pixel region and surrounding a portion of each of the plurality of pixel regions. According to some embodiments, the plurality of conductive patterns include a shielding pattern arranged on at least one of the plurality of insulating layers and overlapping at least a portion of the step pattern in a plan view, at least a portion of the shielding pattern being applied with voltage.

### BRIEF DESCRIPTION OF THE FIGURES

The accompanying drawings are included to provide a further understanding of embodiments according to the present disclosure, and are incorporated in and constitute a part of this specification. The drawings illustrate aspects of some embodiments of the present disclosure and, together with the description, serve to explain aspects of some embodiments of the present disclosure. In the drawings:

FIG. 1 is a combined perspective view of an electronic device according to some embodiments of the present disclosure;

FIG. 2 is an exploded perspective view of an electronic device according to some embodiments of the present disclosure;

FIG. 3 is a block diagram illustrating an electronic device according to some embodiments of the present disclosure;

FIG. 4 is a block diagram illustrating a display module according to some embodiments of the present disclosure;

FIG. 5 is a cross-sectional view of a display module according to some embodiments of the present disclosure;

FIG. 6A is a cross-sectional view of a portion of a display panel included in a display module according to some embodiments of the present disclosure;

FIG. 6B is a cross-sectional view of a portion of a display panel according to some embodiments of the present disclosure;

FIG. 7 is a cross-sectional view of a light-emitting element according to some embodiments of the present disclosure;

FIGS. 8A to 8E are enlarged plan views of a portion of a display module according to some embodiments of the present disclosure;

FIGS. 9A and 9B are cross-sectional views of a display panel according to some embodiments of the present disclosure;

FIGS. 10A to 10C are enlarged cross-sectional views of a portion of a display panel according to some embodiments of the present disclosure;

FIGS. 11A to 11D are enlarged plan views of a portion of a display module according to some embodiments of the present disclosure; and

FIG. 12 is an enlarged plan view of a display module according to some embodiments of the present disclosure.

### DETAILED DESCRIPTION

Hereinafter, aspects of some embodiments of the present disclosure will be described in more detail with reference to the accompanying drawings.

It will be understood that when an element (or a region, layer, portion, or the like) is referred to as being “on”, “connected to”, or “coupled to” another element, it can be directly on or directly connected/coupled to the other element, or a third element may be present therebetween.

The same reference numerals refer to the same elements. In the drawings, the thicknesses, ratios, and dimensions of elements are exaggerated for clarity of illustration. As used herein, the term “and/or” includes any combinations that can be defined by associated elements.

The terms “first”, “second” and the like may be used for describing various elements, but the elements should not be construed as being limited by the terms. Such terms are only used for distinguishing one element from other elements. For example, a first element could be termed a second element and vice versa without departing from the scope of the right of the present invention. The terms of a singular form may include plural forms unless otherwise specified.

Furthermore, the terms “under”, “lower side”, “on”, “upper side”, and the like are used to describe association relationships among elements illustrated in the drawings. The terms, which are relative concepts, are used on the basis of directions illustrated in the drawings.

It will be further understood that the terms “include”, “including”, “has”, “having”, and the like, when used in this specification, specify the presence of stated features, numbers, steps, operations, elements, components, or combinations thereof, but do not preclude the presence or addition of one or more other features, numbers, steps, operations, elements, components, or combinations thereof.

The term “directly arranged” used herein may indicate that there is no additional layer, film, region, plate, or the like between a portion such as a layer, film, region, plate, or the like and another portion. For example, the term “directly arranged” may indicate that two layers or two members are arranged without an additional member such as an adhesive or the like therebetween.

All of the terms used herein (including technical and scientific terms) have the same meanings as understood by those skilled in the art, unless otherwise defined. Terms in common usage such as those defined in commonly used dictionaries should be interpreted to contextually match the lexical meanings in the relevant art, and should not be interpreted in an idealized or overly formal sense unless otherwise defined explicitly.

Hereinafter, further details of a display device according to some embodiments of the present disclosure will be described with reference to the accompanying drawings.

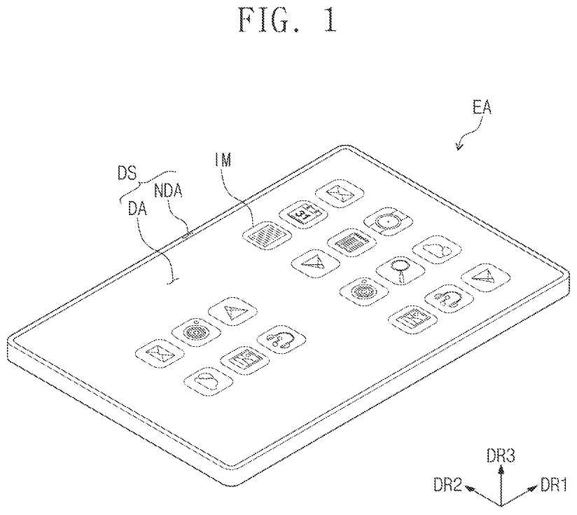

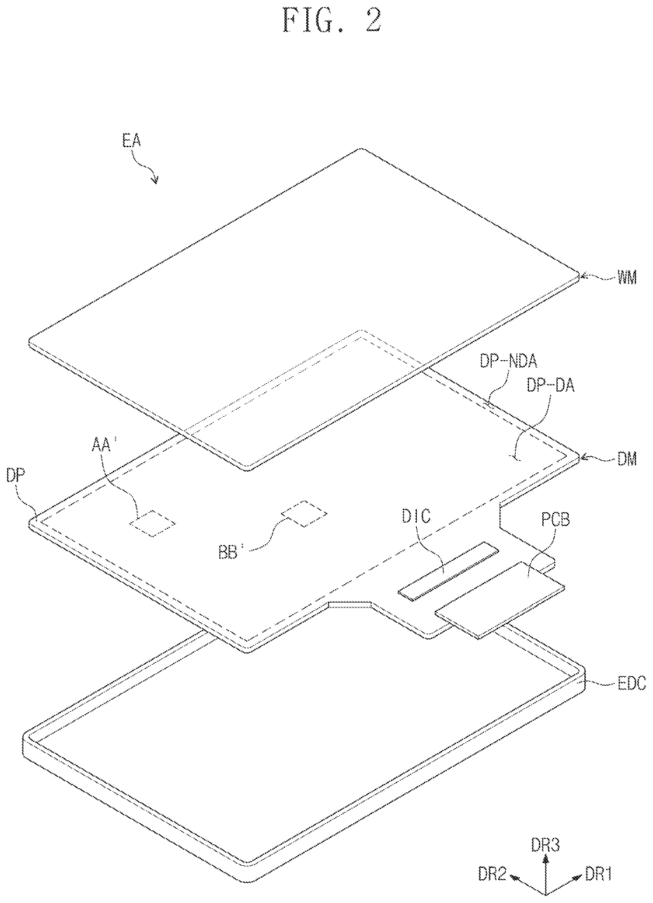

FIG. 1 is a combined perspective view of an electronic device according to some embodiments of the present disclosure. FIG. 2 is an exploded perspective view of an electronic device according to some embodiments of the present disclosure.

Referring to FIG. 1, an electronic device EA may be a device activated in response to an electric signal. The electronic device EA may display an image IM and detect an external input. The electronic device EA may include various embodiments. For example, the electronic device EA may include a tablet PC, a laptop computer, a computer, a smartphone, a television, etc. According to some embodiments, the electronic device EA is illustrated as a tablet PC. However, aspects of some embodiments of the present disclosure not limited thereto, and the electronic device according to some embodiments may be a smartphone. Alternatively, the electronic device according to some embodiments may be a large display device such as a laptop computer, a monitor, or a television. Meanwhile, although FIG. 1 illustrates the rigid electronic device EA, embodiments according to the present disclosure are not limited thereto, and the electronic device EA may be a flexible electronic device, at least a partial area of which is changed in shape according to a usage mode.

The electronic device EA may display the image IM in a third direction DR3 on a display surface DS parallel to each of a first direction DR1 and a second direction DR2. The display surface DS, on which the image IM is displayed, may correspond to a front surface of the electronic device EA and may correspond to a front surface FS of a window WM. Hereinafter, the display surface and front surface of the electronic device EA and the front surface of the window WM will be referred to by the same reference sign. The image IM may include not only a dynamic image but also a still image. A plurality of icons are illustrated as an example of the image IM in FIG. 1.

According to some embodiments, front surfaces (or top surface) and rear surfaces (or bottom surfaces) of members are defined based on the direction in which the image IM is displayed. The front surfaces and the rear surfaces may oppose each other in the third direction DR3, and a normal direction of each of the front surfaces and the rear surfaces may be parallel with the third direction DR3. A distance between each of the front surfaces and each of the rear surfaces may correspond to a thickness of the electronic device EA in the third direction DR3. The directions indicated by the first to third directions DR1 to DR3 are relative concept and thus may be changed to other directions. Hereinafter, first to third directions which are indicated by the first to third directions DR1 to DR3 will be referred to by the same reference symbols. Furthermore, the term “in a plan view” used herein may represent a view from a plane defined by the first direction DR1 and the second direction DR2.

The electronic device EA according to some embodiments of the present disclosure may sense a user input applied externally. The user input includes various types of external inputs such as a part of a user's body, light, heat, or pressure. The user input may be provided in various forms, and, the electronic device EA may detect the user input applied to a side or rear surface of the electronic device EA according to a structure of the electronic device EA, and is not limited to a certain embodiment.

As illustrated in FIG. 2, the electronic device EA includes the window WM, a display module DM, and an external case EDC. According to some embodiments, the window WM and the external case EDC are coupled to each other to form an exterior of the electronic device EA. According to some embodiments, the external case EDC, the display module DM, and the window WM may be sequentially stacked in the third direction DR3.

The window WM may include an optically clear material. The window WM may include an insulating panel. For example, the window WM may include glass, plastic, or a combination thereof.

The front surface FS of the window WM defines the front surface of the electronic device EA, as described above.

The window WM may include a bezel region and a transmissive region. The transmissive region may be an optically clear region. For example, the transmissive region may be a region having at least about 90% transmittance of visual light.

The bezel region may have a relatively low light transmittance compared to the transmissive region. The bezel region defines a shape of the transmissive region. The bezel region may be adjacent to and surround the transmissive region. The bezel region may have a color (e.g., a set or predetermined color). The bezel region may overlap a non-display region DP-NDA of the display panel DP that will be described later. The bezel region may cover the non-display region DP-NDA of the display panel DP to prevent or reduce external visibility of the non-display region DP-NDA. However, this is merely an example, and the bezel region may not be provided to the window WM according to some embodiments of the present disclosure.

The display module DM may include at least the display panel DP. Although FIG. 2 only illustrates the display panel DP among stacked structures of the display module DM, the display module DM may substantially further include a plurality of elements arranged on and under the display panel DP. A stack structure of the display module DM will be described in detail later.

The display panel DP includes a display region DP-DA and non-display region DP-NDA corresponding to the display region DA (see FIG. 1) and non-display region NDA (see FIG. 1) of the electronic device EA. In the present disclosure, the wording “region/portion corresponds to another region/portion” represents “overlapping each other”, but is not limited to cases in which the regions/portions have the same area size. The display module DM may include a driving chip DIC arranged on the non-display region DP-NDA. The display module DM may further include a printed circuit board PCB coupled to the non-display region DP-NDA. The printed circuit board PCB may be electrically connected to pads arranged in the non-display region DP-NDA of the display panel DP through an anisotropic conductive adhesive layer.

The driving chip DIC may include driving elements, for example, data driving circuit, for driving pixels of the display panel DP. Although FIG. 2 illustrates a structure in which the driving chip DIC is mounted on the display panel DP, embodiments according to the present disclosure are not limited thereto. For example, the driving chip DIC may also be mounted on the printed circuit board PCB.

The external case EDC may accommodate the display module DM and may be is coupled to the window WM. The external case EDC may protect elements accommodated in the external case EDC, such as the display module DM.

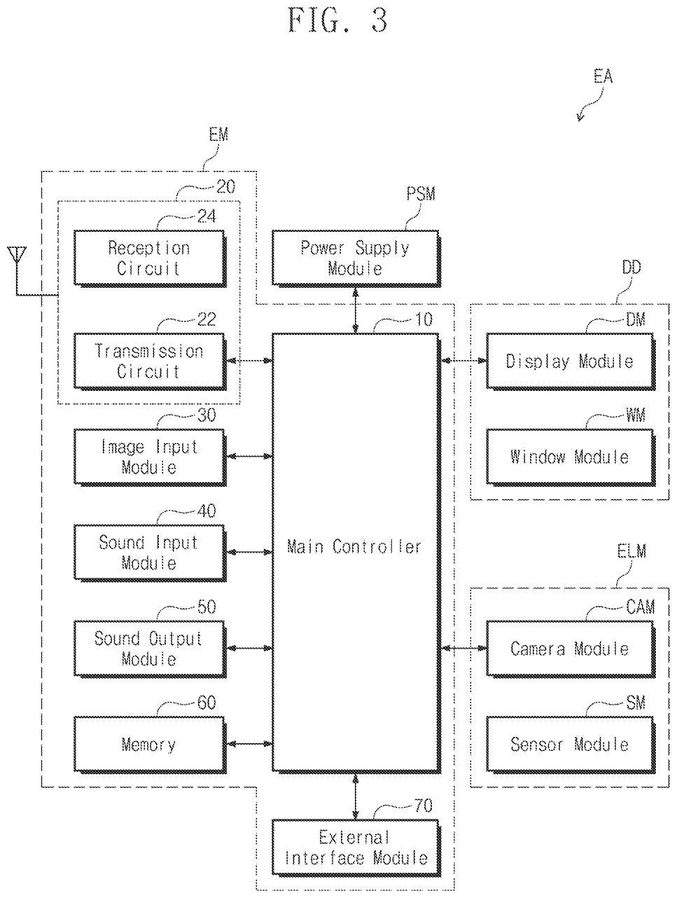

FIG. 3 is a block diagram illustrating an electronic device according to some embodiments of the present disclosure. FIG. 3 schematically illustrates elements included in the electronic device EA described above through a block diagram.

A display device DD may generate an image and detect an external input. The display device DD may include the window WM and the display module DM.

A control module EM may include at least a main controller 10. The control module EM may include the main controller 10, a wireless communication module 20, an image input module 30, a sound input module 40, a sound output module 50, a memory 60, and an external interface module 70. The above modules may be mounted on the printed circuit board or may be electrically connected through a flexible circuit board. The control module EM may be electrically connected to a power supply module PSM.

The main controller 10 controls overall operation of the electronic device EA. For examples, the main controller 10 enables or disables the display device DD in accordance with a user input. The main controller 10 may control the image input module 30, the sound input module 40, the sound output module 50, etc. in accordance with a user input. The main controller 10 may include at least one microprocessor.

The wireless communication module 20 may transmit/receive a wireless signal to/from another terminal using a Bluetooth or WiFi line. The wireless communication module 20 may transmit/receive a voice signal using a general communication line. The wireless communication module 20 includes a transmission circuit 22, which modulates and transmits a signal to be transmitted, and a reception circuit 24, which demodulates a received signal.

The image input module 30 processes an image signal to convert the image signal into image data that is able to be displayed on the display device DD. The sound input module 40 receives an external sound signal through a microphone in a recording mode, a voice recognition mode, or the like, and converts the external sound signal into electric voice data. The sound output module 50 converts sound data received from the wireless communication module 20 or sound data stored in the memory 60 and outputs the converted sound data externally.

The external interface module 70 serves as an interface connected to an external charger, a wired/wireless data port, a card socket (e.g., a memory card, a SIM/UIM card), or the like.

An electronic module ELM may be an electronic component for outputting or receiving an optical signal. The electronic module ELM may be arranged under the display device DD. In the display panel DP of the display device DD, a signal transmissive region having higher light transmittance than another region is defined, and the electronic module ELM transmits or receives an optical signal through a partial region corresponding to the signal transmissive region. According to some embodiments, the electronic module ELM may include a camera module CM. The camera module CM may receive a natural light signal and capture an external image. The electronic module ELM may include a sensor module SM such as a proximity sensor, an ultraviolet light sensor, or the like. The sensor module SM may recognize a part of a user (e.g., fingerprint, iris, or face) or measure a distance between an object and a cell phone.

The power supply module PSM supplies power required for overall operation of the electronic device EA. The power supply module PSM may include a typical battery device.

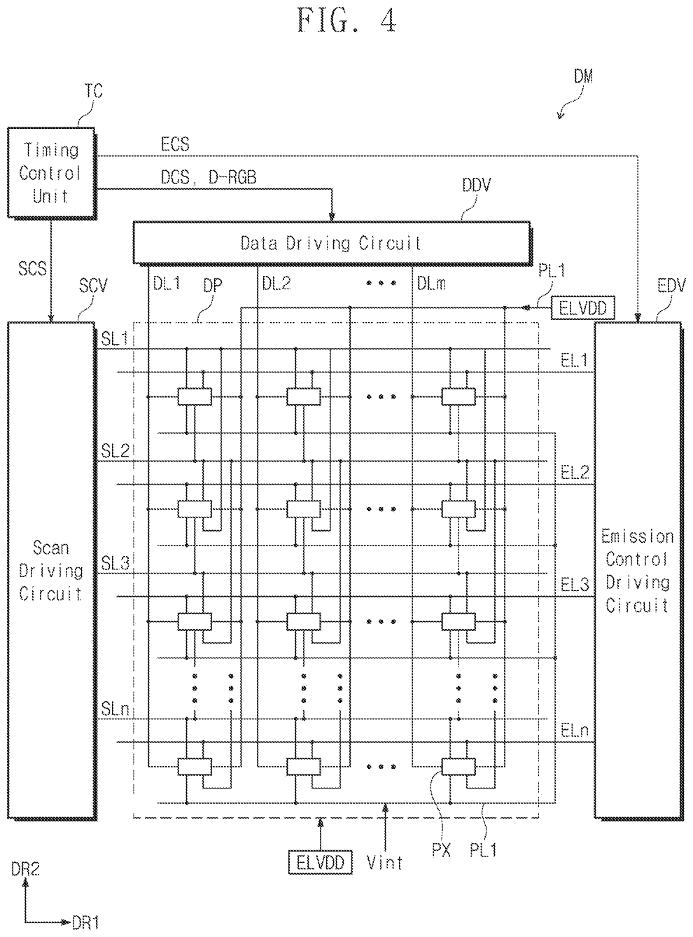

FIG. 4 is a block diagram illustrating a display module according to some embodiments of the present disclosure. The display module DM according to some embodiments of the present disclosure may be a device including at least one semiconductor. The display module DM may include a timing control unit TC, a scan driving circuit SCV, a data driving circuit DDV, an emission control driving circuit EDV, and the display panel DP. The display panel DP display an image according to an electric signal.

According to some embodiments, the display panel DP is described as an organic light-emitting display panel. However, this is merely an example, and the display panel DP according to the present disclosure may include various embodiments.

The timing control unit TC receives input image signals, and generates pieces of image data D-RGB by converting a data format of the input image signals so that the input image signals are compatible with a specification of an interface with the scan driving circuit SCV. The timing control unit TC outputs the pieces of image data D-RGB and various control signals DCS, SCS, and ECS.

The scan driving circuit SCV receives a scan control signal SCS from the timing control unit TC. The scan control signal SCS may include a vertical initiation signal for initiating operation of the scan driving circuit SCV and a clock signal for determining output time of signals.

The scan driving circuit SCV generates a plurality of scan signals, and sequentially outputs the plurality of scan signals to a plurality of scan lines SL1 to SLn.

The emission control driving circuit EDV receives an emission control signal ECS from the timing control unit TC. The emission control driving circuit EDV generates a plurality of emission control signals in response to the emission control signal ECS, and outputs the emission control signals to a plurality of emission lines EL1 to ELn.

Although the scan signals and the emission control signals are described as being separately output from the scan driving circuit SCV and the emission control driving circuit EDV, respectively, embodiments of the present disclosure are not limited thereto, and the emission control driving circuit EDV may not be provided, and the scan signals and the emission control signals may be output from the scan driving circuit SCV.

The data driving circuit DDV receives the data control signal DCS and the pieces of image data D-RGB from the timing control unit TC. The data driving circuit DDV converts the pieces of image data D-RGB into data signals, and outputs the data signals to data lines DL1 to DLm (DL). The data signals are analog voltages corresponding to gradation values of the pieces of image data D-RGB.

The display panel DP includes the scan lines SL1 to SLn, the emission lines EL1 to ELn, the data lines DL1 to DLm, and pixels PX. The scan lines SL1 to SLn extend in the first direction DR1 and are arranged in the second direction DR2 intersecting the first direction DR1.

Each of the emission lines EL1 to ELn may be arranged in parallel with a corresponding scan line among the scan lines SL1 to SLn. The data lines DL1 to DLm insulatively intersect the scan lines SL1 to SLn.

Each of the pixels PX is connected to a corresponding scan line among the scan lines SL1 to SLn, a corresponding emission line among the emission lines EL1 to ELn, and a corresponding data line among the data lines DL1 to DLm.

Each of the pixels PX receives a first power supply voltage ELVDD and a second power supply voltage ELVSS lower than the first power supply voltage ELVDD. Each of the pixels PX is connected to a driving power supply line PL to which the first power supply voltage ELVDD is applied. Each of the pixels PX is connected to an initialization line RL which receives an initialization voltage Vint.

Each of the pixels PX may be electrically connected to three scan lines. As illustrated in FIG. 4, pixels of a second pixel row may be connected to the first to third scan line SL1 to SL3.

The display panel DP may further include a plurality of dummy scan lines. The display panel DP may further include a dummy scan line connected to the pixels PX of a first pixel row and a dummy scan line connected to the pixels PX of an n-th pixel row. Furthermore, pixels (hereinafter, pixels of a pixel column) connected to any one of the data lines DL1 to DLm may be connected to each other. Two adjacent pixels among pixels of a pixel column may be electrically connected. However, this is merely an example, and a connection relationship between the pixels PX according to some embodiments of the present disclosure may be variously designed, and is not limited to a certain embodiment.

Each of the pixels PX includes a light-emitting element and a pixel driving circuit for controlling light emission of the light-emitting element. The pixel driving circuit may include a thin film transistor and a capacitor.

According to some embodiments, at least one of the scan driving circuit SCV, the emission control driving circuit EDV, or the data driving circuit DDV may include thin film transistors formed through the same process as the pixel driving circuit. For example, the scan driving circuit SCV, the emission control driving circuit EDV, and the data driving circuit DDV all may be mounted on the display panel DP. Alternatively, two of the scan driving circuit SCV, the emission control driving circuit EDV, and the data driving circuit DDV may be mounted on the display panel DP, and the remaining one may be provided on the printed circuit board PCB (see FIG. 2) or may be provided to the separate driving chip DIC (see FIG. 2) independent of the display panel DP and connected to the display panel DP.

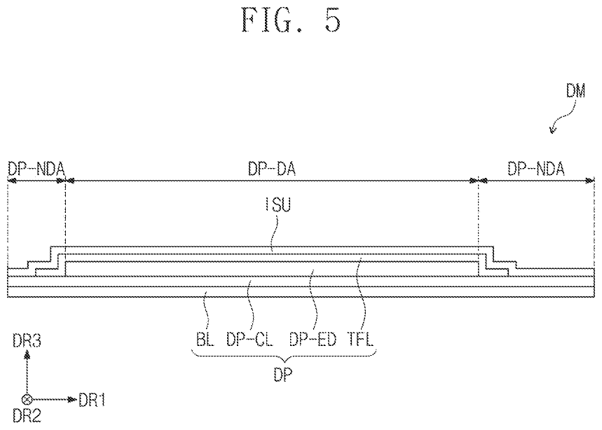

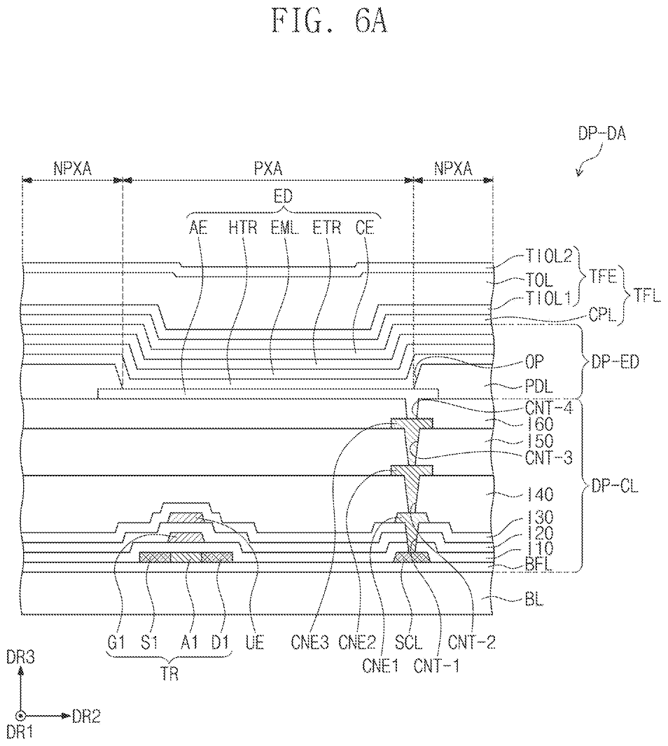

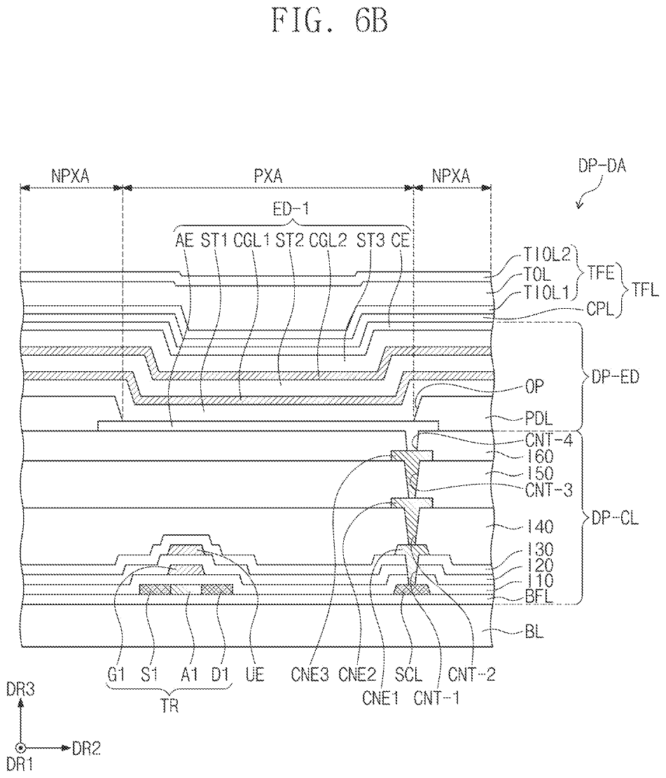

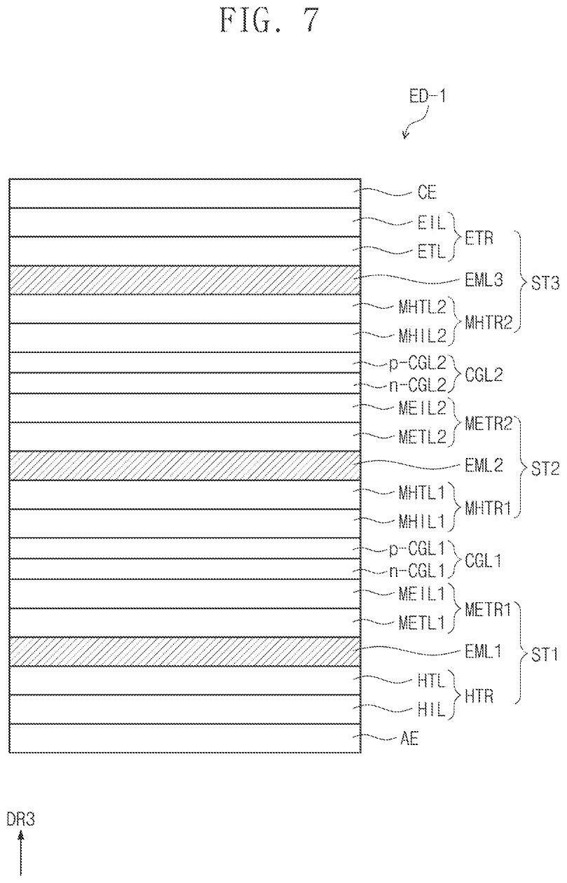

FIG. 5 is a cross-sectional view of a display module according to some embodiments of the present disclosure. FIG. 6A is a cross-sectional view of a portion of a display panel included in a display module according to some embodiments of the present disclosure. FIG. 6B is a cross-sectional view of a portion of a display panel according to some embodiments of the present disclosure. FIG. 7 is a cross-sectional view of a light-emitting element according to some embodiments of the present disclosure. FIGS. 6A and 6B each illustrate, as an example, a light-emitting element and transistor included in one pixel of a display panel according to some embodiments.

Referring to FIG. 5, the display module DM may include the display panel DP and an input sensing unit ISU. The display panel DP may substantially generate the image IM (see FIG. 1). The image IM (see FIG. 1) generated by the display panel DP may be externally viewed by the user through the display region DA (see FIG. 1).

The display panel DP may be an emissive display panel, but is not particularly limited. For example, the display panel DP may be an organic light-emitting display panel or an inorganic light-emitting display panel. The organic light-emitting display panel may be a display panel in which an emission layer includes an organic light-emitting material. The inorganic light-emitting display panel may be a display panel in which an emission layer includes a quantum dot, quantum rod, or micro LED. The display panel DP is described as an organic light-emitting display panel below.

The input sensing unit ISU may be arranged on the display panel DP. The input sensing unit ISU may sense an external input applied externally. The external input may include various types of inputs provided from the outside of the electronic device EA (see FIG. 1). The inputs provided from the outside may be provided in various forms. For example, the external input may include not only a contact by a part of body, such as a user's hand, but also an external input (e.g., hovering) that is in proximity to the electronic device EA or is provided within a distance (e.g., a set or predetermined distance) from the electronic device EA. Furthermore, the external input may be in a form of force, pressure, light, etc., and is not limited to a certain embodiment.

The input sensing unit ISU may be formed on the display panel DP through a continuous process. In this case, the input sensing unit ISU may be directly arranged on the display panel DP. Meanwhile, in the present disclosure, the wording “element B is directly arranged on element A” may indicate that a third component is not arranged between the element A and the element B. For example, an adhesive layer may not be arranged between the input sensing unit ISU and the display panel DP.

The display panel DP may include a base layer BL, and a circuit layer DP-CL, a light-emitting element layer DP-ED, and an upper insulating layer TFL arranged on the base layer BL.

The base layer BL may provide a base surface on which the circuit layer DP-CL, the light-emitting element layer DP-ED, and the upper insulating layer TFL are arranged. The base layer BL may be a rigid substrate or a flexible substrate that is bendable, foldable, or rollable. The base layer BL may be a glass substrate, a metal substrate, a polymer substrate, or the like. However, aspects of embodiments of the present disclosure are not limited thereto, and the base layer BL may include an inorganic layer, an organic layer, or a composite material layer.

The base layer BL may have a multi-layer structure. For example, the base layer BL may include a first synthetic resin layer, an inorganic single-layer or multi-layer, and a second synthetic resin layer arranged on the inorganic single-layer or multi-layer. Each of the first and second synthetic resin layers may include a polyimide-based resin, but is not particularly limited.

The circuit layer DP-CL may be arranged on the base layer BL. The circuit layer DP-CL may include a plurality of insulating layers, a plurality of conductive layers, and a semiconductor layer. The plurality of conductive layers of the circuit layer DP-CL may constitute signal lines or a control circuit of a pixel.

The light-emitting element layer DP-ED may be arranged on the circuit layer DP-CL. The light-emitting element layer DP-ED may include light-emitting elements. The light-emitting element layer DP-ED may include, for example, organic light-emitting elements. However, this is merely an example, and the light-emitting element layer DP-ED according to some embodiments of the present disclosure may include inorganic light-emitting elements, organic-inorganic light-emitting elements, or a liquid crystal layer. The light-emitting element layer DP-ED may further include a pixel defining structure. In the pixel defining structure, a pixel opening in which a light-emitting element is arranged may be defined.

The upper insulating layer TFL may include a capping layer and an encapsulation layer that will be described later. The encapsulation layer may include an organic layer and a plurality of inorganic layers sealing the organic layer.

The upper insulating layer TFL may be arranged on the light-emitting element layer DP-ED to protect the light-emitting element layer DP-ED from moisture, oxygen, and foreign matter such as dust particles. The upper insulating layer TFL may seal the light-emitting element layer DP-ED to block moisture and oxygen introducing to the light-emitting element layer DP-ED. The upper insulating layer TFL may include at least one inorganic layer. The upper insulating layer TFL may include an organic layer and a plurality of inorganic layers sealing the organic layer. The upper insulating layer TFL may include a stack structure in which layers are stacked in order of inorganic layer/organic layer/inorganic layer.

The input sensing unit ISU is arranged on the upper insulating layer TFL. The input sensing unit ISU may be formed on the upper insulating layer TFL through a continuous process. The input sensing unit ISU may be directly arranged on the display panel DP. That is, an additional adhesive member may not be arranged between the input sensing unit ISU and the display panel DP. The input sensing unit ISU may be arranged in contact with an inorganic layer arranged in an uppermost portion of the upper insulating layer TFL.

According to some embodiments, the display module DM may further include a protective member arranged on a lower surface of the display panel DP and an anti-reflective member arranged on an upper surface of the input sensing unit ISU. The anti-reflective member may reduce reflectance of external light. The anti-reflective member may be directly arranged on the input sensing unit ISU through a continuous process.

The anti-reflective member may include a light shielding pattern overlapping a reflective structure arranged under the anti-reflective member. The anti-reflective member may further include a color filter. The color filter may include a first-color color filter, a second-color color filter, and a third-color color filter corresponding to a first-color pixel, a second-color pixel, and a third-color pixel and arranged between light shielding patterns.

As illustrated in FIG. 5, the display panel DP may be divided into the display region DP-DA and the non-display region DP-NDA in a plan view. The display region DP-DA of the display panel DP may be a region in which an image is displayed, and the non-display region DP-NDA may be a region in which a driving circuit, driving wiring, and the like are arranged. Light-emitting elements of each of a plurality of pixels may be arranged in the display region DP-DA. The display region DP-DA may overlap at least a portion of the transmissive region of the window WM (see FIG. 2), and the non-display region DP-NDA may be covered with the bezel region of the window WM. The display region DP-DA and the non-display region DP-NDA of the display panel DP may respectively correspond to the display region DA and the non-display region NDA of the electronic device EA illustrated in FIG. 1.

Referring to FIGS. 5 and 6A, in the display panel DP according to some embodiments, the circuit layer DP-CL, the light-emitting element layer DP-ED, and the upper insulating layer TFL may be sequentially arranged on the base layer BL. The circuit layer DP-CL, the light-emitting element layer DP-ED, and the upper insulating layer TFL will be described in detail with reference to FIG. 6A.

The circuit layer DP-CL includes at least one insulating layer and a circuit element. The circuit element includes a signal line, a pixel driving circuit, etc. The circuit layer DP-CL may be formed through a process of forming an insulating layer, a semiconductor layer, and a conductive layer by coating, deposition, or the like and a process of patterning the insulating layer, the semiconductor layer, and the conductive layer by photolithography.

A buffer layer BFL may include at least one stacked inorganic layer. A semiconductor pattern is arranged on the buffer layer BFL. The buffer layer BFL improves a bonding force between the base layer BL and the semiconductor pattern.

The semiconductor pattern may include polysilicon. However, embodiments of the present disclosure are not limited thereto, and, thus, the semiconductor pattern may include amorphous silicon or metal oxide. FIG. 6A only illustrates a partial semiconductor pattern, and another semiconductor pattern may be further arranged in another region of a pixel in a plan view. The semiconductor patterns may be arranged over pixels according to a particular rule.

The semiconductor pattern may have different electric properties according to whether the semiconductor pattern is doped. The semiconductor pattern may include a first region A1 having low doping concentration and conductivity and second regions S1 and D1 having relatively high doping concentration and conductivity. One second region S1 may be arranged at one side of the first region A1, and the other second region D1 may be arranged at the other side of the first region A1. The second regions S1 and D1 may be doped with an N-type dopant or P-type dopant. A P-type transistor includes a doped region doped with a P-type dopant. The first region A1 may be a non-doped region or a region doped at a lower concentration than that of the second regions S1 and D1.

The second regions S1 and D1 may substantially function as an electrode or a signal line. One second region S1 may correspond to a source of a transistor TR, and other one second region D1 may correspond to a drain. FIG. 6A illustrates a portion of a connection signal line SCL formed from the semiconductor pattern. According to some embodiments, the connection signal line SCL may be connected to the drain of the transistor TR in a plan view.

A first insulating layer 110 may be arranged on the buffer layer BFL. The first insulating layer 110 commonly overlaps a plurality of pixels arranged in the display region DP-DA, and covers the semiconductor pattern. The first insulating layer 110 may be an inorganic layer and/or organic layer, and may have a single-layer or multi-layer structure. The first insulating layer 110 may include at least one of aluminum oxide, titanium oxide, silicon oxide, silicon oxynitride, zirconium oxide, or hafnium oxide. Not only the first insulating layer 110 but also the insulating layer of the circuit layer DP-CL described below may be an inorganic layer and/or organic layer, and may have a single-layer or multi-layer structure.

A gate G1 is arranged on the first insulating layer 110. The gate G1 may be a portion of a metal pattern. The gate G1 overlaps the first region A1. The gate G1 may function as a mask during a process of doping a semiconductor pattern.

A second insulating layer 120 may be arranged on the first insulating layer 110, and may cover the gate G1. The second insulating layer 120 commonly overlaps pixels. An upper electrode UE may be arranged on the second insulating layer 120. The upper electrode UE may overlap the gate G1. The upper electrode UE may include a metal multi-layer. According to some embodiments of the present disclosure, the upper electrode UE may not be provided.

A third insulating layer 130 may be arranged on the second insulating layer 120, and may cover the upper electrode UE. A first connection electrode CNE1 may be arranged on the third insulating layer 130. The first connection electrode CNE1 may be connected to the connection signal line SCL through a contact hole CNT-1 penetrating the first to third insulating layers 110 to 130.

A fourth insulating layer 140 may be arranged on the third insulating layer 130, and a fifth insulating layer 150 may be arranged on the fourth insulating layer 140. The fourth insulating layer 140 may be an organic layer. A second connection electrode CNE2 may be arranged on the fourth insulating layer 140. The second connection electrode CNE2 may be connected to the first connection electrode CNE1 through a contact hole CNT-2 penetrating the fourth insulating layer 140.

The fifth insulating layer 150 may be arranged on the fourth insulating layer 140, and may be an organic layer. A third connection electrode CNE3 may be arranged on the fifth insulating layer 150. The third connection electrode CNE3 may be connected to the second connection electrode CNE2 through a contact hole CNT-3 penetrating the fifth insulating layer 150.

A sixth insulating layer 160 may be arranged on the fifth insulating layer 150, and may cover the third connection electrode CNE3. The sixth insulating layer 160 may be an organic layer.

A light-emitting element ED may be arranged on the sixth insulating layer 160. The light-emitting element ED may include a first electrode AE, a hole transport region HTR, an emission layer EML, an electron transport region ETR, and a second electrode CE, which are sequentially stacked.

The first electrode AE of the light-emitting element ED may be arranged on the sixth insulating layer 160. The first electrode AE is connected to the third connection electrode CNE3 through a contact hole CNT-4 penetrating the sixth insulating layer 160. A pixel opening OP is defined in a pixel defining layer PDL so that the pixel defining layer PDL exposes at least a portion of the first electrode AE. The pixel defining layer PDL may be an organic layer.

As illustrated in FIG. 6B, the display region DP-DA may include a pixel region PXA and a non-pixel region NPXA adjacent thereto. The non-pixel region NPXA may surround the pixel region PXA. According to some embodiments, the pixel region PXA is defined to correspond to a partial region of the first electrode AE exposed by the pixel opening OP.

The hole transport region HTR may be arranged commonly in the pixel region PXA and the non-pixel region NPXA. The hole transport region HTR may include a hole transport layer and may further include a hole injection layer. The emission layer EML is arranged on the hole transport region HTR.

The electron transport region ETR may be arranged on the emission layer EML. The electron transport region ETR may include an electron transport layer and may further include an electron injection layer. The hole transport region HTR, the emission layer EML, and the electron transport region ETR may be formed commonly in a plurality of pixels using an open mask. However, embodiments of the present disclosure are not limited thereto, and at least one of the hole transport region HTR, the emission layer EML, or the electron transport region ETR may be formed by being patterned through a mask. For example, the emission layer EML may be arranged in a region corresponding to the pixel opening OP. That is, the emission layer EML may be separately formed in each pixel.

The second electrode CE may be arranged on the electron transport region ETR. The second electrode CE may have a shape of a single body, and may be arranged commonly in a plurality of pixels.

The upper insulating layer TFL may be arranged on the light-emitting element layer DP-ED and may include a plurality of thin films. According to some embodiments of the present disclosure, the upper insulating layer TFL may include a capping layer CPL and an encapsulation layer TFE arranged on the capping layer CPL. The capping layer CPL is located on the second electrode CE and contacts the second electrode CE. The capping layer CPL may include an organic material. The capping layer CPL may have a refractive index of at least about 1.6 in a wavelength range of about 550 nm to about 660 nm.

The encapsulation layer may include a first inorganic encapsulation layer TIOL1, an organic encapsulation layer TOL arranged on the first inorganic encapsulation layer TIOL1, and a second inorganic encapsulation layer TIOL2 arranged on the organic encapsulation layer TOL. The inorganic encapsulation layer TIOL1 and the second inorganic encapsulation layer TIOL2 protect the light-emitting element layer DP-ED from moisture/oxygen, and the organic encapsulation layer TOL protects the light-emitting element layer DP-ED from foreign matter such as particles of dust.

FIG. 6B illustrates a portion of a display panel including a light-emitting element ED-1 different from the embodiments illustrated with respect to FIG. 6A. FIG. 7 schematically illustrates the stack structure of the light-emitting element ED-1 illustrated in FIG. 6B. Hereinafter, when describing the display panel according to embodiments with reference to FIG. 6B, the same reference signs will be provided for the configuration described above with reference to FIG. 6A and some detailed descriptions thereof may not be provided.

Referring to FIGS. 6B and 7, the light-emitting element ED-1 included in a display panel according to some embodiments may include a plurality of light-emitting stacks ST1, ST2, and ST3 and charge generation layers CGL1 and CGL2 arranged between the plurality of light-emitting stacks ST1, ST2, and ST3. The light-emitting element ED-1 according to some embodiments may include the first electrode AE, the first light-emitting stack ST1, the first charge generation layer CGL1, the second light-emitting stack ST2, the second charge generation layer CGL2, the third light-emitting stack ST3, and the second electrode CE, which are sequentially stacked. Although FIG. 6B illustrates that the light-emitting element ED-1 includes three light-emitting stacks ST1, ST2, and ST3 and two charge generation layers CGL1 and CGL2 arranged therebetween, embodiments of the present disclosure are not limited thereto, and the light-emitting element ED-1 may include two light-emitting stacks or at least four light-emitting stacks.

The plurality of light-emitting stacks ST1, ST2, and ST3 each may include the emission layer EML (see FIG. 6B) and a hole control layer and electron control layer with the emission layer EML (see FIG. 6B) therebetween. According to some embodiments, the first light-emitting stack ST1 may include a first emission layer, the second light-emitting stack ST2 may include a second emission layer, and the third light-emitting stack ST3 may include a third emission layer. That is, the light-emitting element ED-1 may be a light-emitting element having a tandem structure including a plurality of light-emitting stacks that include emission layers.

In the embodiments illustrated with respect to FIG. 6B, light emitted from each of the plurality of light-emitting stacks ST1, ST2, and ST3 may have the same wavelength. For example, the light emitted from each of the plurality of light-emitting stacks ST1, ST2, and ST3 may be blue light. However, embodiments of the present disclosure are not limited thereto, and the plurality of light-emitting stacks ST1, ST2, and ST3 may emit light of different wavelength regions. For example, at least one of the plurality of light-emitting stacks ST1, ST2, or ST3 may emit blue light and other stacks may emit green light. The light-emitting element ED-1 including the plurality of light-emitting stacks ST1, ST2, and ST3 that emit light of different wavelength regions may emit white light.

The charge generation layers CGL1 and CGL2 may be arranged between neighboring light-emitting stacks ST1, ST2, and ST3.

Referring to FIG. 7, according to some embodiments, the light-emitting element ED-1 may emit light in a direction from the first electrode AE to the second electrode CE. The light-emitting element ED-1 according to some embodiments is illustrated as having a structure in which the hole transport region HTR and intermediate hole transport regions MHTR1 and MHTR2 are arranged under emission layers EML1, EML2, and EML3 of respective stacks, on the basis of a direction of light emission, and the electron transport region ETR and intermediate electron transport regions METR1 and METR2 are arranged on the emission layers EML1, EML2, and EML3 of respective stacks. However, embodiments of the present disclosure are not limited thereto, and the light-emitting element ED-1 may have an inverted element structure in which the electron transport region ETR is arranged under the emission layers EML1, EML2, and EML3 of respective stacks, on the basis of the direction of light emission, and the hole transport region HTR is arranged on the emission layers EML1, EML2, and EML3 of respective stacks.

The light-emitting element ED-1 according to some embodiments may include the charge generation layers CGL1 and CGL2 arranged between the plurality of stacks ST1, ST2, and ST3. The light-emitting element ED-1 according to some embodiments may include the first charge generation layer CGL1 arranged between the first light-emitting stack ST1 and the second light-emitting stack ST2, and the second charge generation layer CGL2 arranged between the second light-emitting stack ST2 and the third light-emitting stack ST3.

When being applied with voltage, the charge generation layers CGL1 and CGL2 may generate charges (electrons and holes) by forming complexes through oxidation-reduction reaction. Furthermore, the charge generation layers CGL1 and CGL2 may provide generated charges to adjacent stacks ST1, ST2, and ST3. The charge generation layers CGL1 and CGL2 may double efficiency of current generated in respective adjacent stacks ST1, ST2, and ST3, and may function to adjust balance of charges between adjacent stacks ST1, ST2, and ST3.

The charge generation layers CGL1 and CGL2 each may have a layer structure in which n-type charge generation layers n-CGL1 and n-CGL2 and p-type charge generation layers p-CGL1 and p-CGL2 are bonded to each other. The first charge generation layer CGL1 may have a layer structure in which the first n-type charge generation layer n-CGL1 and the first p-type charge generation layer p-CGL1 are bonded to each other. The second charge generation layer CGL2 may have a layer structure in which the second n-type charge generation layer n-CGL2 and the second p-type charge generation layer p-CGL2 are bonded to each other. The third charge generation layer CGL3 may have a layer structure in which the third n-type charge generation layer n-CGL3 and the third p-type charge generation layer p-CGL3 are bonded to each other.

The n-type charge generation layers n-CGL1 and n-CGL2 may be charge generation layers that provide electrons to adjacent stacks. The n-type charge generation layers n-CGL1 and n-CGL2 may be layers in which a base material is doped with n-dopant. The p-type charge generation layers p-CGL1 and p-CGL2 may be charge generation layers that provide holes to adjacent stacks. According to some embodiments, a buffer layer may be further arranged between the n-type charge generation layers n-CGL1 and n-CGL2 and the p-type charge generation layers p-CGL1 and p-CGL2.

The charge generation layers CGL1 and CGL2 each may include an n-type aryl amine-based material or p-type metal oxide. For example, the charge generation layers CGL1 and CGL2 each may include an aryl amine-based organic compound, metal, metal oxide, carbide, fluoride, or a charge generating compound composed of a mixture thereof.

For example, the aryl amine-based organic compound may include α-NPD, 2-TNATA, TDATA, MTDATA, sprio-TAD, or sprio-NPB. For example, the metal may include cesium (Cs), molybdenum (Mo), vanadium (V), titanium (Ti), tungsten (W), barium (Ba), or lithium (Li). Furthermore, for example, the metal oxide, carbide, and fluoride may include Re₂O₇, MoO₃, V₂O₅, WO₃, TiO₂, CS₂CO₃, BaF, LiF, or CsF.

In the light-emitting element ED-1 according to some embodiments, the first light-emitting stack ST1, the second light-emitting stack ST2, and the third light-emitting stack ST3 respectively include the emission layers EML1, EML2, and EML3 that emit light of a particular wavelength. For example, the emission layers EML1, EML2, and EML3 may emit light of a first wavelength, wherein the light of the first wavelength may be light of a blue wavelength region. According to some embodiments, the light of the first wavelength may be light of a wavelength region of about 410 nm to about 480 nm. The emission layers EML1, EML2, and EML3 each may include a host material and a blue light-emitting dopant. A dopant included in the emission layers EML1, EML2, and EML3 may be a blue fluorescent dopant. The emission layers EML1, EML2, and EML3 may include the same host material and dopant material. At least a portion of the emission layers EML1, EML2, and EML3 may emit light of a second wavelength or light of a third wavelength aside from the light of the first wavelength. The light of the second wavelength may be light of a green wavelength region. According to some embodiments, the light of the second wavelength may be light of a wavelength region of about 500 nm to about 600 nm. The light of the third wavelength may be light of a red wavelength region. According to some embodiments, the light of the third wavelength may be light of a wavelength region of about 620 nm to about 700 nm.

The first light-emitting stack ST1 may further include the hole transport region HTR for transporting holes provided from the first electrode AE to the first emission layer EML1 and the first intermediate electron transport region METR1 for transporting electrons generated from the first charge generation layer CGL1 to the first emission layer EML1.

The hole transport region HTR may include a hole injection layer HIL arranged on the first electrode AE and a hole transport layer HTL arranged on the hole injection layer HIL. The hole transport layer HTL may be in contact with a lower surface of the first emission layer EML1. However, embodiments of the present disclosure are not limited thereto, and the hole transport region HTR may further include a hole-side additional layer arranged on the hole transport layer HTL. The hole-side additional layer may include at least one of a hole buffer layer, an emission auxiliary layer, or an electron blocking layer. The hole buffer layer may be a layer, which increases light emission efficiency by compensating for a resonance distance according to a wavelength of light emitted from an emission layer. The electron blocking layer may be a layer, which functions to prevent or reduce injection of electrons from an electronic transport region to a hole transport region.

The first intermediate electron transport region METR1 may include a first intermediate electron transport layer METL1 arranged on the first emission layer EML1. The first intermediate electron transport layer METL1 may be arranged between the first emission layer EML1 and the first charge generation layer CGL1 and may contact the first emission layer EML1. The first intermediate electron transport region METR1 may further include a first intermediate electron injection layer MEIL1 arranged between the first intermediate electron transport layer METL1 and the first charge generation layer CGL1. The first intermediate electron transport region METR1 may further include a first intermediate electron-side additional layer arranged between the first intermediate electron transport layer METL1 and the first emission layer EML1. The first intermediate electron-side additional layer may include at least one of an electron buffer layer or a hole blocking layer.

The second light-emitting stack ST2 may further include a first intermediate hole transport region MHTR1 for transporting holes generated from the first charge generation layer CGL1 to the second emission layer EML2 and a second intermediate electron transport region METR2 for transporting electrons provided from the second charge generation layer CGL2 to the second emission layer EML2.

The first intermediate hole transport region MHTR1 may include a first intermediate hole injection layer MHIL1 arranged on the first charge generation layer CGL1 and a first intermediate hole transport layer MHTL1 arranged on the first intermediate hole injection layer MHIL1. The first intermediate hole transport layer MHTL1 may be in contact with a lower surface of the second emission layer EML2. However, embodiments of the present disclosure are not limited thereto, and the first intermediate hole transport region MHTR1 may further include a first intermediate hole-side additional layer arranged on the first intermediate hole transport layer MHTL1. The first intermediate hole-side additional layer may include at least one of a hole buffer layer, an emission auxiliary layer, or an electron blocking layer.

The second intermediate electron transport region METR2 may include a second intermediate electron transport layer METL2 arranged on the second emission layer EML2. The second intermediate electron transport layer METL2 may be arranged between the second emission layer EML2 and the second charge generation layer CGL2 and may contact the second emission layer EML2. The second intermediate electron transport region METR2 may further include a second intermediate electron injection layer MEIL2 arranged between the second intermediate electron transport layer METL2 and the second charge generation layer CGL2. The second intermediate electron transport region METR2 may further include a second intermediate electron-side additional layer arranged between the second intermediate electron transport layer METL2 and the second emission layer EML2. The second intermediate electron-side additional layer may include at least one of an electron buffer layer or a hole blocking layer.

The third light-emitting stack ST3 may further include a second intermediate hole transport region MHTR2 for transporting holes generated from the second charge generation layer CGL2 to the third emission layer EML3 and the electron transport region ETR for transporting electrons provided from the third charge generation layer CGL3 to the third emission layer EML3.

The second intermediate hole transport region MHTR2 may include a second intermediate hole injection layer MHIL2 arranged on the second charge generation layer CGL2 and a second intermediate hole transport layer MHTL2 arranged on the second intermediate hole injection layer MHIL2. The second intermediate hole transport layer MHTL2 may be in contact with a lower surface of the third emission layer EML3. However, embodiments of the present disclosure are not limited thereto, and the second intermediate hole transport region MHTR2 may further include a second intermediate hole-side additional layer arranged on the second intermediate hole transport layer MHTL2. The second intermediate hole-side additional layer may include at least one of a hole buffer layer, an emission auxiliary layer, or an electron blocking layer.

The electron transport region ETR may include an electron transport layer ETL arranged on the third emission layer EML3 and an electron injection layer EIL arranged on the electron transport layer ETL. The electron transport layer ETL may be in contact with the third emission layer EML3. However, embodiments of the present disclosure are not limited thereto, and the electron transport region ETR may further include an electron-side additional layer arranged between the electron transport layer ETL and the second emission layer EML2. The electron-side additional layer may include at least one of an electron buffer layer or a hole blocking layer.

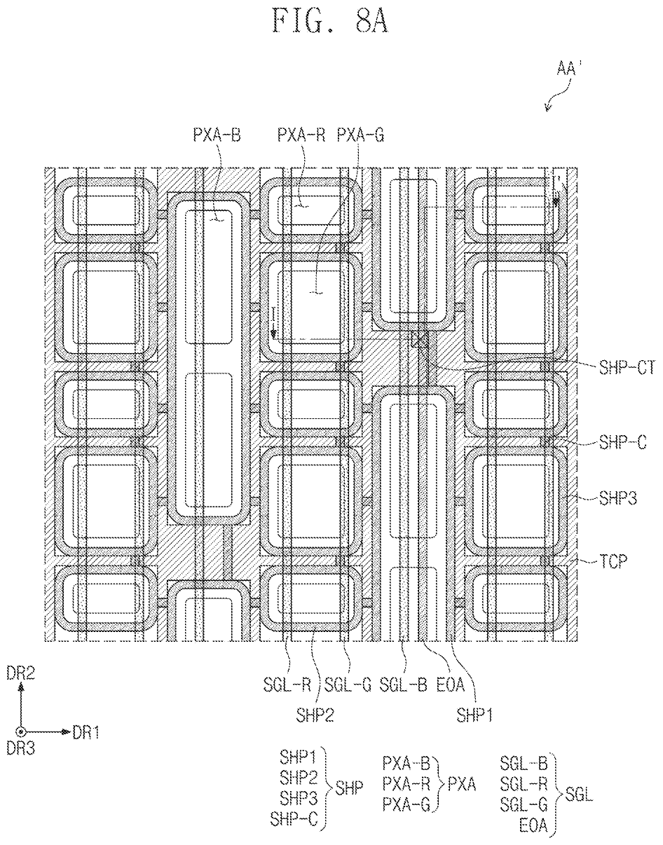

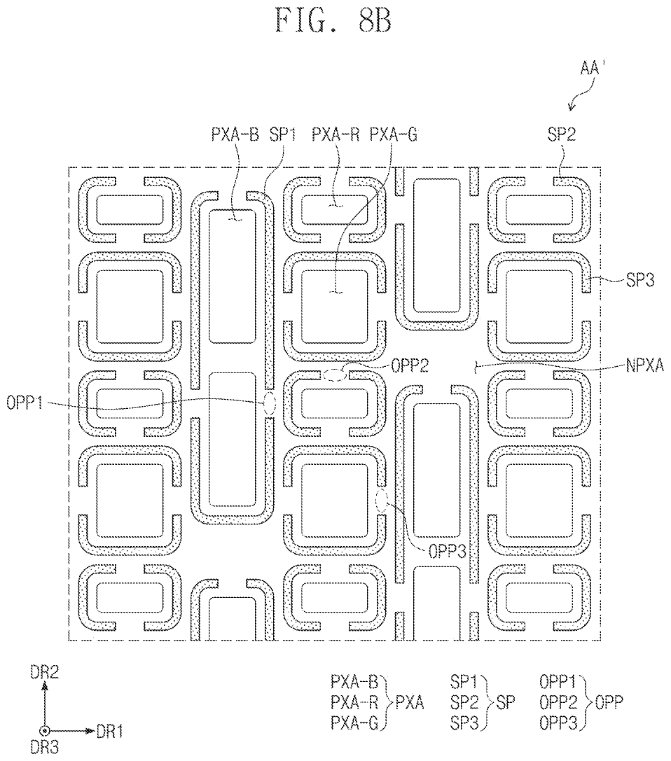

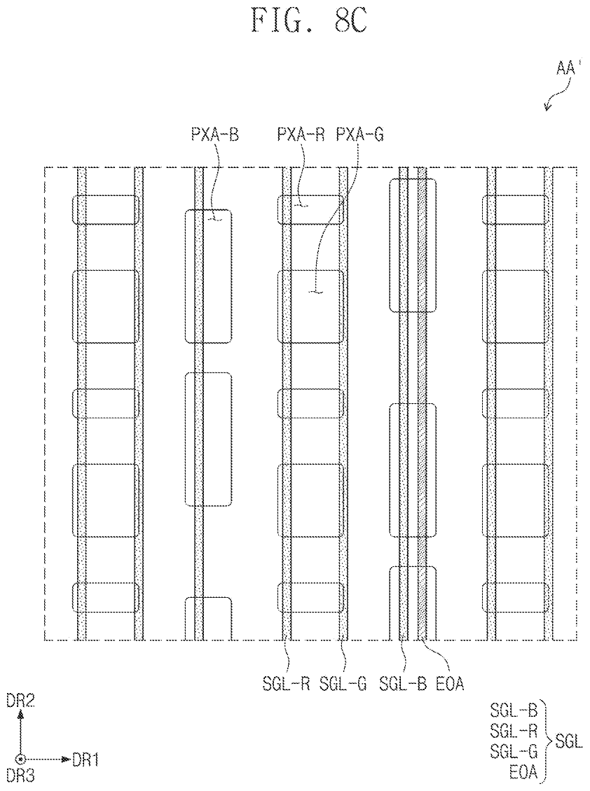

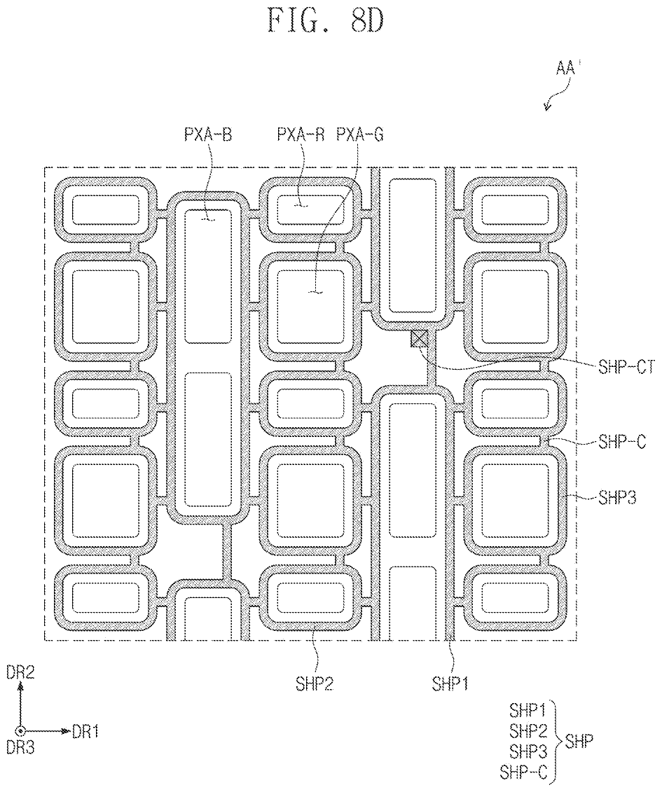

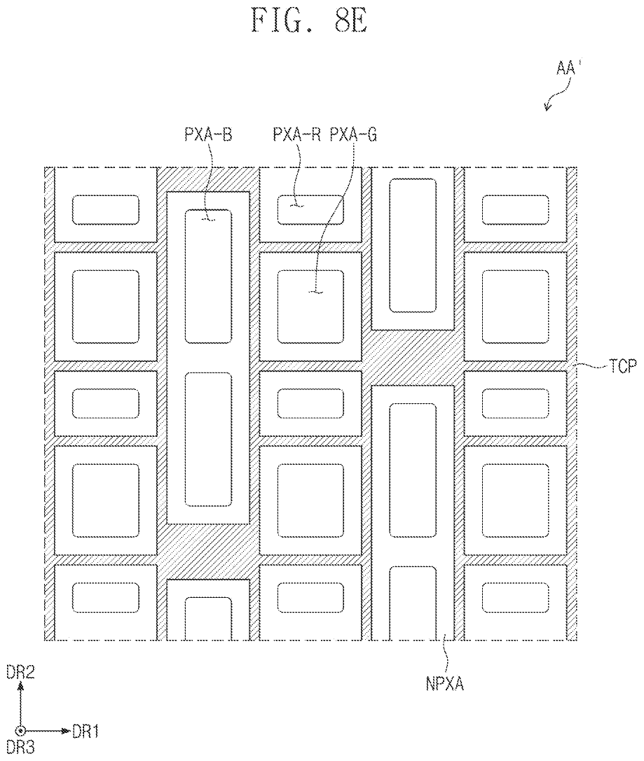

FIGS. 8A to 8E are enlarged plan views of a portion of a display module according to some embodiments of the present disclosure. FIGS. 8A to 8E each illustrate an enlarged view of arrangement of a plurality of pixel regions and a step pattern, blocking pattern, signal line, and sensing electrode defined adjacent to the plurality of pixel regions in the AA′ region illustrated in FIG. 2. FIG. 8B illustrates arrangement of a plurality of pixel regions PXA and shapes of step patterns SP arranged adjacent to the plurality of pixel regions PXA respectively, among the elements illustrated in FIG. 8A. FIG. 8C illustrates arrangement of the plurality of pixel regions PXA and shapes of signal lines SGL arranged overlapping at least a portion of the plurality of pixel regions PXA, among the elements illustrated in FIG. 8A. FIG. 8D illustrates arrangement of the plurality of pixel regions PXA and shapes of shielding patterns SHP arranged adjacent to the plurality of pixel regions PXA respectively, among the elements illustrated in FIG. 8A. FIG. 8E illustrates arrangement of the plurality of pixel regions PXA and shapes of sensing patterns TCP arranged adjacent to the plurality of pixel regions PXA respectively, among the elements illustrated in FIG. 8A.

Referring to FIGS. 2 and 8A to 8E, in the display panel DP according to some embodiments, the display region DP-DA may include the plurality of pixel regions PXA and the non-pixel region NPXA surrounding the plurality of pixel regions PXA. The plurality of pixel regions PXA may include a first pixel region PXA-B, a second pixel region PXA-R, and a third pixel region PXA-G. The first pixel region PXA-B, the second pixel region PXA-R, and the third pixel region PXA-G each may display light of a different wavelength. The first pixel region PXA-B may display first light of a blue light wavelength, the second pixel region PXA-R may display second light of a red light wavelength, and the third pixel region PXA-G may display third light of a green light wavelength.

The plurality of pixel regions PXA may be divided by the above-mentioned pixel defining layer PDL (see FIG. 6B). The non-pixel region NPXA, which is a region between neighboring pixel regions PXA, may correspond to the pixel defining layer PDL (see FIG. 6B). Herein, each of the plurality of pixel regions PXA may correspond to a “pixel”. The plurality of pixel regions PXA may be divided so as to correspond to the pixel opening OP (see FIG. 6B) defined in the pixel defining layer PDL (see FIG. 6B).

As illustrated in FIG. 8A, the first pixel regions PXA-B may constitute a first pixel group in which the first pixel regions PXA-B are arranged along the second direction DR2, and the second pixel regions PXA-R and the third pixel regions PXA-G may constitute a second pixel group in which the second pixel regions PXA-R and the third pixel regions PXA-G are alternately arranged along the second direction DR2. The first pixel group including the first pixel regions PXA-B and the second pixel group including the second pixel regions PXA-R and the third pixel regions PXA-G may be spaced apart in the first direction DR1. The first pixel group and the second pixel group may be alternately arranged in the first direction DR1.

The plurality of pixel regions PXA-B, PXA-R, and PXA-G may have different area sizes according to a wavelength of emitted light. For example, as illustrated in FIG. 8A, the first pixel region PXA-B, which emits the first light, may have a largest area size, and the second pixel region PXA-R, which emits the second light, may have a smallest area size. However, embodiments according to the present disclosure are not limited thereto, and the pixel regions PXA-B, PXA-R, and PXA-G may have the same area size, or may be defined at an area size ratio different from that illustrated in FIG. 8A. The plurality of pixel regions PXA-B, PXA-R, and PXA-G may emit light of color other than the light of a blue light wavelength, the light of a red light wavelength, and the light of a green light wavelength, described above.

The plurality of pixel regions PXA-B, PXA-R, and PXA-G each may have a rectangular shape with rounded corners in a plan view. According to some embodiments, the first pixel region PXA-B and the third pixel region PXA-G each may have a rectangular shape with rounded corners having a long side extending in the second direction DR2 and a short side extending in the first direction DR1. According to some embodiments, the second pixel region PXA-R may have a rectangular shape with rounded corners having a long side extending in the first direction DR1 and a short side extending in the second direction DR2.

Referring to FIGS. 8A and 8B, the display panel DP according to some embodiments includes step patterns SP, which are adjacent to the plurality of pixel regions PXA-B, PXA-R, and PXA-G, overlap the non-pixel region NPXA, and surround a portion of each of the plurality of pixel regions PXA-B, PXA-R, and PXA-G. Each of the step patterns SP surrounds a portion of each of the plurality of pixel regions PXA-B, PXA-R, and PXA-G and does not surround another portion thereof. Herein, a portion, which does not surround the plurality of pixel regions PXA-B, PXA-R, and PXA-G, of the step pattern SP is defined as an “open portion OPP”. A proportion of the open portion OPP in each of the step patterns SP may be about 10% to about 50%. When the proportion of the open portion OPP in each of the step patterns SP is less than about 10%, a driving voltage may excessively increase, and thus efficiency of a display device may reduce. When the proportion of the open portion OPP in each of the step patterns SP exceeds about 50%, lateral leakage current may excessively occur, and thus color mixing may occur between adjacent pixels, causing deterioration of optical characteristics of a display device. The proportion of the open portion OPP in each of the step patterns SP may be referred to as an “open ratio of the second electrode CE”.

The step pattern SP is arranged on the above-mentioned pixel defining layer PDL (see FIG. 6A) or defined in the pixel defining layer PDL (see FIG. 6A). The step pattern SP may have a surface forming a step with an upper surface of the pixel defining layer PDL (see FIG. 6A) in the third direction DR3. In a cross-sectional view, the step pattern SP may have a shape that is recessed from the upper surface of the pixel defining layer PDL (see FIG. 6A) in a thickness direction of the pixel defining layer PDL (see FIG. 6A), or may include a protruding structure arranged on the pixel defining layer PDL (see FIG. 6A) and having an inversely tapered shape. A cross-sectional shape of the step pattern SP will be described in detail later.

The step pattern SP may include a first step pattern SP1 surrounding a portion of the first pixel region PXA-B, a second step pattern SP2 surrounding a portion of the second pixel region PXA-R, and a third step pattern SP3 surrounding a portion of the third pixel region PXA-G. The first step pattern SP1, the second step pattern SP2, and the third step pattern SP3 each may surround a portion of each of the first pixel region PXA-B, the second pixel region PXA-R, and the third pixel region PXA-G and may not surround another portion thereof.

A first open portion OPP1 not surrounding a portion of the first pixel region PXA-B is defined in the first step pattern SP1, a second open portion OPP2 not surrounding a portion of the second pixel region PXA-R is defined in the second step pattern SP2, and a third open portion OPP3 not surrounding a portion of the third pixel region PXA-G is defined in the third step pattern SP3.

In the first step pattern SP1, the second step pattern SP2, and the third step pattern SP3, which are respectively defined in the first pixel region PXA-B, the second pixel region PXA-R, and the third pixel region PXA-G arranged adjacent to each other, the first open portion OPP1, the second open portion OPP2, and the third open portion OPP3 respectively defined in the first step pattern SP1, the second step pattern SP2, and the third step pattern SP3 are defined so as not to face each other in a plan view. Herein, open portions being “defined so as not to face each other in a plan view” indicate that open portions of valley regions defined in respective pixel regions do not overlap each other at a portion in which a shortest distance between valley regions is defined, as illustrated in FIG. 8B. For example, the first open portion OPP1 is defined in the first step pattern SP1 defined around the first pixel region PXA-B, and an open portion is not defined in a portion of the second step pattern SP2 and a portion of the third step pattern SP3, which are closest to the portion in which the first open portion OPP1 is defined. Likewise, an open portion is not defined in a portion of the first step pattern SP1 and a portion of the third step pattern SP3, which are closest to the portion in which the second open portion OPP2 is defined, and an open portion is not defined in a portion of the first step pattern SP1 and a portion of the second step pattern SP2, which are closest to the portion in which the third open portion OPP3 is defined.

The first open portion OPP1, the second open portion OPP2, and the third open portion OPP3 each may be defined on one side of each of the first pixel region PXA-B, the second pixel region PXA-R, and the third pixel region PXA-G. For example, as illustrated in FIG. 8B, the first step pattern SP1 may be arranged surrounding two first pixel regions PXA-B, and the first open portion OPP1 may be defined adjacent to a short side extending in the first direction DR1 and a long side extending in the second direction DR2 in the first pixel region PXA-B. The second step pattern SP2 may be arranged surrounding one second pixel region PXA-R, the second open portion OPP2 may be defined adjacent to a long side extending in the first direction DR1 in the second pixel region PXA-R, the third step pattern SP3 may be arranged surrounding one third pixel region PXA-G, and the third open portion OPP3 may be defined adjacent to a long side extending in the second direction DR2 in the third pixel region PXA-G. As illustrated in FIG. 8B, the first open portion OPP1 may be defined adjacent to a long side corresponding to an end in the first direction DR1 and a short side corresponding to an end in the second direction DR2 in the first pixel region PXA-B, the second open portion OPP2 may be defined adjacent to a long side corresponding to an end in the second direction DR2 in the second pixel region PXA-R, and the third open portion OPP3 may be defined adjacent to a long side corresponding to an end in the first direction DR1 in the third pixel region PXA-G.

According to some embodiments, when the long side extending in the second direction DR2 is defined as a first side and the short side extending in the first direction DR1 is defined as a second side in the first pixel region PXA-B, the first open portion OPP1 may be defined on the first side. When the short side extending in the second direction DR2 is defined as a third side, and the long side extending in the first direction DR1 is defined as a fourth side in the second pixel region PXA-R, the second open portion OPP2 may be defined on the fourth side. That is, in the first pixel region PXA-B and the second pixel region PXA-R arranged adjacent to each other, the first open portion OPP1 and the second open portion OPP2, which are defined in the first step pattern SP1 and the second step pattern SP2 arranged adjacent to the first pixel region PXA-B and the second pixel region PXA-R respectively, may be defined so as to have different extension directions.

In a display device according to some embodiments, the step patterns SP surrounding a portion of each of pixel regions are defined in order to prevent or reduce the occurrence of lateral leakage current between neighboring pixels. Herein, the “lateral leakage current” represents a current flowing in a direction intersecting the third direction DR3, except for a current flowing in the third direction DR3, which is a stack direction of a light-emitting element, i.e., a direction in which an image is displayed. The lateral leakage current may represent a current flowing in a direction parallel with a plane defined by the first direction DR1 and the second direction DR2. In a display device according to some embodiments, because the step pattern SP, which is recessed in a thickness direction of a pixel defining layer, is formed, the occurrence of the lateral leakage current may be prevented or reduced, thus preventing or reducing color mixing between adjacent pixel regions and deterioration of luminance.

Meanwhile, in a display device according to some embodiments, the open portions OPP1, OPP2, and OPP3 are respectively formed in the step patterns SP in order to prevent or reduce instances a driving voltage increasing excessively. Furthermore, in a display device according to some embodiments, the open portions OPP1, OPP2, and OPP3 may be defined so as not to face each other in the step patterns SP defined in adjacent pixel regions respectively. When the open portions OPP1, OPP2, and OPP3 are defined so as to face each other, the lateral leakage current may occur between adjacent pixels in which the open portions OPP1, OPP2, and OPP3 facing each other are defined. However, in a display device according to some embodiments, because the open portions OPP1, OPP2, and OPP3 are defined so as not to face each other, a current may be prevented from flowing in a direction of a plane defined by the first direction DR1 and the second direction DR2 other than an intended direction. Accordingly, the driving voltage of a display device may be prevented from increasing, and color mixing between adjacent pixels and luminance deterioration may be prevented or reduced, thus relatively improving the display efficiency of the display device.

Referring to FIGS. 8A and 8C, in the display panel DP according to some embodiments, a portion of the signal line SGL may be arranged overlapping each of the plurality of pixel regions PXA-B, PXA-R, and PXA-G in a plan view. The signal line SGL may include at least one of the scan lines SL1 to SLn (see FIG. 4), the emission lines EL1 to ELn (see FIG. 4), or the data lines DL1 to DLm (see FIG. 4), described above. For example, the signal line SGL may include data lines connected to pixels arranged in the plurality of pixel regions PXA-B, PXA-R, and PXA-G. The signal line SGL may be included in the above-mentioned circuit layer DP-CL (see FIG. 6A) and may be arranged on one of a plurality of insulating layers included in the DP-CL (see FIG. 6A).

Meanwhile, the term “overlapping in a plan view” used herein may represent overlapping when viewed from a plane defined by the first direction DR1 and the second direction DR2. That is, the term “overlapping in a plan view” may represent being arranged in parallel and overlapping in the third direction DR3 that is a thickness direction.

The signal line SGL may include a first signal line SGL-B overlapping the first pixel region PXA-B, a second signal line SGL-R overlapping the second pixel region PXA-R, and a third signal line SGL-G overlapping the third pixel region PXA-G. The first signal line SGL-B may overlap the first pixel region PXA-B and may be connected to a pixel arranged in the first pixel region PXA-B to supply a data signal. The second signal line SGL-R may overlap the second pixel region PXA-R and may be connected to a pixel arranged in the second pixel region PXA-R to supply a data signal. The third signal line SGL-G may overlap the third pixel region PXA-G and may be connected to a pixel arranged in the third pixel region PXA-G to supply a data signal.

The signal line SGL may further include an active voltage line EOA overlapping at least one of the plurality of pixel regions PXA-B, PXA-R, or PXA-G. As illustrated in FIG. 8C, the active voltage line EOA may be arranged overlapping the first pixel region PXA-B. The active voltage line EOA may be electrically connected to the shielding pattern SHP that will be described later and may provide a voltage (e.g., a set or predetermined voltage) to the shielding pattern SHP. The active voltage line EOA may provide a DC voltage to the shielding pattern SHP. For example, the active voltage line EOA may provide the second power supply voltage ELVSS (see FIG. 4) to the shielding pattern SHP. Furthermore, the active voltage line EOA may provide the first power supply voltage ELVDD (see FIG. 4).

The active voltage line EOA may be arranged in the same layer as other wiring included in the signal line SGL or may be arranged in a different layer. According to some embodiments, the active voltage line EOA and the first to third signal lines SGL-B, SGL-R, and SGL-G may be arranged on the same layer among the plurality of insulating layers included in the circuit layer DP-CL (see FIG. 6A). Alternatively, the active voltage line EOA may be arranged on an insulating layer different from that of the first to third signal lines SGL-B, SGL-R, and SGL-G.

Referring to FIGS. 8A and 8D, the display panel DP according to some embodiments includes shielding patterns SHP, which are adjacent to the plurality of pixel regions PXA-B, PXA-R, and PXA-G, overlap the non-pixel region NPXA, and surround at least a portion of each of the plurality of pixel regions PXA-B, PXA-R, and PXA-G. A voltage (e.g., a set or predetermined voltage) is applied to at least a portion of the shielding patterns SHP. A DC voltage may be applied to the shielding patterns SHP. For example, the second power supply voltage ELVSS (see FIG. 4) may be applied to the shielding patterns SHP.

Each of the shielding patterns SHP surrounds at least a portion of each of the plurality of pixel regions PXA-B, PXA-R, and PXA-G. As illustrated in FIG. 8D, the shielding patterns SHP may be arranged so as to completely surround each of the plurality of pixel regions PXA-B, PXA-R, and PXA-G in a plan view. The shielding patterns SHP may be included in the above-mentioned circuit layer DP-CL (see FIG. 6A) and may be arranged on one of a plurality of insulating layers included in the DP-CL (see FIG. 6A).

Referring to FIGS. 8A, 8B, and 8D, the shielding pattern SHP is arranged overlapping the step pattern SP in a plan view. The shielding pattern SHP may have a shape corresponding to the step pattern SP in a plan view. Meanwhile, the above-mentioned step pattern SP may entirely overlap the shielding pattern SHP. The term “entirely overlap” used herein may represent that an entirety of one element overlaps at least a portion of another element. That is, when “A entirely overlaps B in a plan view”, the entirety of A is arranged in parallel with and overlaps at least a portion of B in the third direction DR3. An entirety of a portion in which the step pattern SP is arranged may overlap a portion in which the shielding pattern SHP is arranged in a plan view.

The shielding pattern SHP may have a shape corresponding to the open portion OPP defined in the step pattern SP in a plan view. Because the open portion OPP is defined in the above-mentioned step pattern SP, the step pattern SP has a shape that does not surround a portion of the plurality of pixel regions PXA-B, PXA-R, and PXA-G. However, the shielding pattern SHP may be arranged so as to completely surround each of the plurality of pixel regions PXA-B, PXA-R, and PXA-G and overlap a portion, in which the open portion OPP is defined, of the step pattern SP.

The shielding pattern SHP may include a first shielding pattern SHP1 surrounding the first pixel region PXA-B, a second shielding pattern SHP2 surrounding the second pixel region PXA-R, and a third shielding pattern SHP3 surrounding the third pixel region PXA-G.

The shielding pattern SHP may further include a connection shielding pattern SHP-C connecting the first shielding pattern SHP1, the second shielding pattern SHP2, and the third shielding pattern SHP3. The first shielding pattern SHP1, the second shielding pattern SHP2, and the third shielding pattern SHP3 surrounding the plurality of pixel regions PXA-B, PXA-R, and PXA-G respectively may be connected by the connection shielding pattern SHP-C and provided with the same voltage.

Referring to FIGS. 8A and 8D, the shielding pattern SHP may be supplied with a voltage through a shielding contact hole SHP-CT formed in an insulating layer in which the shielding pattern SHP is arranged among a plurality of insulating layers. The shielding contact hole SHP-CT may be formed so as to overlap at least one of the signal lines SGL, or the shielding pattern SHP may be electrically connected to at least one of the signal lines SGL through the shielding contact hole SHP-CT so as to be supplied with a voltage. The shielding contact hole SHP-CT may be formed so as to overlap the active voltage line EOA so that the second power supply voltage ELVSS (see FIG. 4) may be applied to the shielding pattern SHP through the shielding contact hole SHP-CT.

Referring to FIGS. 8A and 8E, the input sensing unit ISU (see FIG. 5) may include the sensing pattern TCP, and the sensing pattern TCP may be arranged overlapping the non-pixel region NPXA. The sensing pattern TCP may overlap the non-pixel region NPXA but may not overlap the plurality of pixel regions PXA.

The sensing pattern TCP may be arranged adjacent to each of the step pattern SP and the shielding pattern SHP in a plan view. As illustrated in FIG. 8A, a portion in which the sensing pattern TCP is arranged and portions in which the step pattern SP and the shielding pattern SHP are arranged may be adjacent to each other in a plan view, and another element may not be arranged therebetween. Although FIGS. 8A to 8E illustrate that the sensing pattern TCP does not overlap each of the step pattern SP and the shielding pattern SHP in a plan view, embodiments of the present disclosure are not limited thereto, and a portion of the sensing pattern TCP may overlap each of the step pattern SP and the shielding pattern SHP.

In a display device according to some embodiments, a step pattern surrounding a portion of each of pixel regions is defined in order to prevent or reduce the occurrence of lateral leakage current between adjacent pixels. However, when a short circuit of a second electrode of a light-emitting element is formed due to the step pattern, total resistance of the second electrode increases, and driving signals or the like generated in a display panel are transferred to an input sensing unit arranged on the display panel, and thus sensitivity of the input sensing unit may deteriorate. In particular, because the sensing pattern included in the input sensing unit is arranged overlapping or at least adjacent to the step pattern, the sensitivity of the sensing pattern may deteriorate due to the short circuit of the second electrode.

In a display device according to some embodiments, the shielding pattern overlapping the step pattern in a plan view is included, and a voltage (e.g., a set or predetermined voltage) such as a second power supply voltage is provided to the shielding pattern so that the shielding pattern may function to block a driving signal or the like generated in the display panel. Therefore, even if a short circuit of the second electrode is formed due to the step pattern, a driving signal generated in the display panel may be prevented from being transferred to the sensing pattern of the input sensing unit, thus preventing or reducing deterioration of the sensitivity of the input sensing unit. Therefore, reliability of a display device and electronic device including the input sensing unit may be improved.

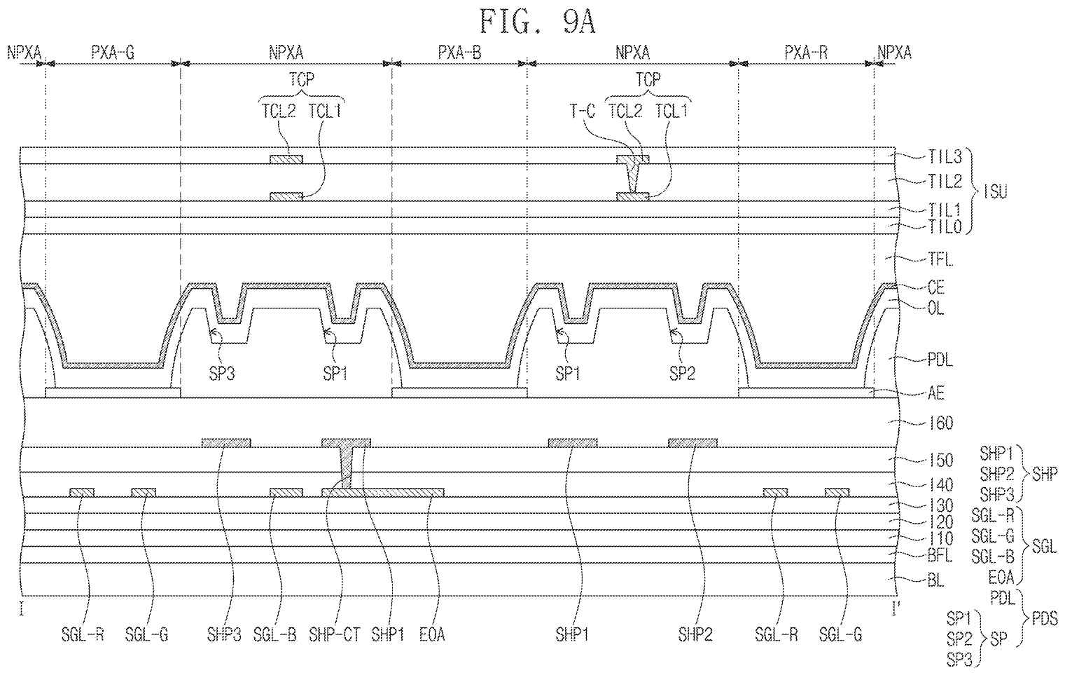

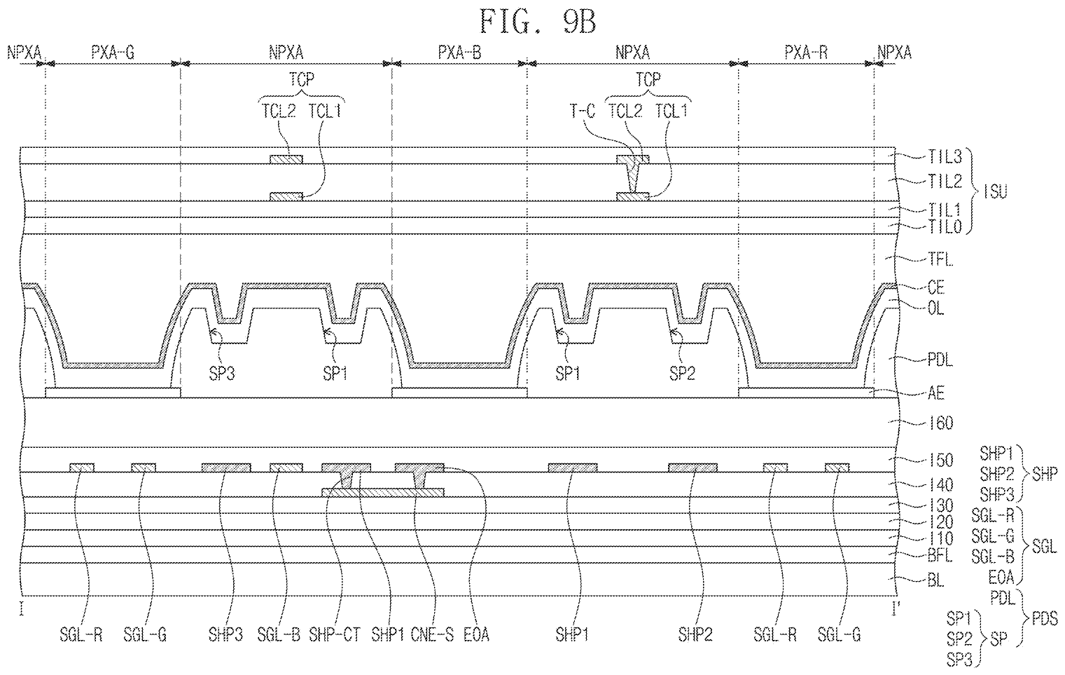

FIGS. 9A and 9B are cross-sectional views of a display panel according to some embodiments of the present disclosure. FIGS. 9A and 9B each illustrate a cross section taken along the line I-I′ illustrated in FIG. 8A.

Referring to FIGS. 8A, 9A, and 9B, the display module DM according to some embodiments includes the base layer BL, the circuit layer DP-CL arranged on the base layer BL, the light-emitting element layer DP-ED arranged on the circuit layer DP-CL, the upper insulating layer TFL arranged on the light-emitting element layer DP-ED, and the input sensing unit ISU arranged on the upper insulating layer TFL.

The circuit layer DP-CL includes the plurality of insulating layers 110, 120, 130, 140, 150, and 160 and a plurality of conductive patterns. The plurality of conductive patterns included in the circuit layer DP-CL may be arranged in the plurality of insulating layers 110, 120, 130, 140, 150, and 160, and may include the above-mentioned signal lines SGL. The plurality of conductive patterns included in the circuit layer DP-CL may include the first signal line SGL-B, the second signal line SGL-R, the third signal line SGL-G, and the active voltage line EOA. According to some embodiments, the above-mentioned transistor TR, a capacitor, etc. may be further included in the circuit layer DP-CL.

The signal lines SGL are arranged on at least one of the plurality of insulating layers 110, 120, 130, 140, 150, or 160. For example, as illustrated in FIG. 9A, the signal lines SGL may be arranged on the third insulating layer 130. Alternatively, as illustrated in FIG. 9B, the signal lines SGL may be arranged on the fourth insulating layer 140. Herein, a layer in which the signal lines SGL are arranged may be referred to as a “first base insulating layer”.

Unlike the illustration, the signal lines SGL may be arranged on a plurality of insulating layers among the plurality of insulating layers 110, 120, 130, 140, 150, and 160. For example, the signal lines SGL may have a double-layer wiring structure in which at least a portion of the signal lines SGL is arranged in two of the plurality of insulating layers 110, 120, 130, 140, 150, and 160. For example, the signal lines SGL may have a double-layer wiring structure in which at least a portion of the first signal line SGL-B, the second signal line SGL-R, the third signal line SGL-G, and the active voltage line EOA is arranged in the third insulating layer 130 and the fourth insulating layer 140.

Although FIGS. 9A and 9B illustrate that the first signal line SGL-B, the second signal line SGL-R, the third signal line SGL-G, and the active voltage line EOA are all arranged in the same layer, embodiments of the present disclosure are not limited thereto, and a portion of the signal lines SGL may be arranged on a layer different from that of other signal lines. For example, the active voltage line EOA may be arranged on an insulating layer different from that of the first signal line SGL-B, the second signal line SGL-R, and the third signal line SGL-G.

The plurality of conductive patterns included in the circuit layer DP-CL include the shielding pattern SHP. The shielding pattern SHP is arranged on one of the plurality of insulating layers 110, 120, 130, 140, 150, and 160. For example, as illustrated in FIG. 9A, the shielding pattern SHP may be arranged on the fifth insulating layer 150. Alternatively, as illustrated in FIG. 9B, the shielding pattern SHP may be arranged on the fourth insulating layer 140. Herein, a layer in which the shielding pattern SHP is arranged may be referred to as a “second base insulating layer”.

The first base insulating layer in which the signal lines SGL are arranged and the second base insulating layer in which the shielding pattern SHP is arranged may be different layers. According to some embodiments, the second base insulating layer may be arranged on the first base insulating layer. For example, as illustrated in FIG. 9A, the signal lines SGL may be arranged on the third insulating layer 130, and the shielding pattern SHP may be arranged on the fifth insulating layer 150. The second base insulating layer in which the shielding pattern SHP is arranged may be a layer arranged above the first base insulating layer in which at least one of the signal lines SGL is arranged. The active voltage line EOA may be arranged on the third insulating layer 130, and the shielding pattern SHP may be arranged on the fifth insulating layer 150.

The shielding contact hole SHP-CT may be defined in a portion of the plurality of insulating layers 110, 120, 130, 140, 150, and 160 so that the shielding pattern SHP may be electrically connected to a portion of the signal lines SGL. The shielding contact hole SHP-CT may be defined in at least the second base insulating layer in which the shielding pattern SHP is arranged. As illustrated in FIG. 9A, the shielding contact hole SHP-CT is defined in the fifth insulating layer 150 that is the second base insulating layer in which the shielding pattern SHP is arranged, and the shielding contact hole SHP-CT penetrates the fifth insulating layer 150 and the fourth insulating layer 140 arranged thereunder so that the shielding pattern SHP may be electrically connected to the active voltage line EOA arranged on the third insulating layer 130. The shielding pattern SHP may be electrically connected to the active voltage line EOA so as to be provided with the second power supply voltage ELVSS (see FIG. 4).

The first base insulating layer in which the signal lines SGL are arranged and the second base insulating layer in which the shielding pattern SHP is arranged may be the same layer. For example, as illustrated in FIG. 9B, the signal lines SGL may be arranged on the fourth insulating layer 140, and the shielding pattern SHP may also be arranged on the fourth insulating layer 140. The second base insulating layer in which the shielding pattern SHP is arranged may be the same layer as the first base insulating layer in which at least one of the signal lines SGL is arranged. The active voltage line EOA may be arranged on the fourth insulating layer 140, and the shielding pattern SHP may also be arranged on the fourth insulating layer 140.

The shielding contact hole SHP-CT may be defined in a portion of the plurality of insulating layers 110, 120, 130, 140, 150, and 160 so that the shielding pattern SHP may be electrically connected to a portion of the signal lines SGL. The shielding contact hole SHP-CT may be defined in at least the second base insulating layer in which the shielding pattern SHP is arranged. As illustrated in FIG. 9B, the shielding contact hole SHP-CT is defined in the fourth insulating layer 140 that is the second base insulating layer in which the shielding pattern SHP is arranged, and the shielding contact hole SHP-CT penetrates the fourth insulating layer 140 so that the shielding pattern SHP may be electrically connected to an additional connection electrode CNE-S. The additional connection electrode CNE-S may be arranged on the third insulating layer 130 and may be electrically connected to the active voltage line EOA. The shielding pattern SHP may be electrically connected to the active voltage line EOA via the additional connection electrode CNE-S so as to be provided with the second power supply voltage ELVSS (see FIG. 4). Unlike the illustration of FIG. 9B, the shielding pattern SHP may be directly connected to the active voltage line EOA without the additional connection electrode CNE-S therebetween.

The light-emitting element ED arranged on the circuit layer DP-CL may include the first electrode AE, an organic layer OL, and the second electrode CE, which are sequentially stacked. The organic layer OL may include at least the emission layer EML (see FIG. 6A). The organic layer OL, for example, may include the hole transport region HTR, the emission layer EML, and the electron transport region ETR, which are sequentially stacked, as described above with reference to FIG. 6A. Alternatively, the organic layer OL may include the plurality of light-emitting stacks ST1, ST2, and ST3 sequentially stacked and the charge generation layers CGL1 and CGL2 arranged between the plurality of light-emitting stacks ST1, ST2, and ST3, as described above with reference to FIG. 6B.

Meanwhile, the first power supply voltage ELVDD (see FIG. 4) may be applied to the first electrode AE of the light-emitting element ED through a driving transistor. The second power supply voltage ELVSS (see FIG. 4) that is different from the first power supply voltage ELVDD (see FIG. 4) applied to the first electrode AE may be applied to the shielding pattern SHP. However, embodiments of the present disclosure are not limited thereto, and the same voltage as the first power supply voltage ELVDD (see FIG. 4) applied to the first electrode AE may be provided to the shielding pattern SHP.

The second power supply voltage ELVSS (see FIG. 4) may be applied to the second electrode CE of the light-emitting element ED. According to some embodiments, a portion of the second electrode CE may contact the shielding pattern SHP. For example, an opening may be formed in a portion of the sixth insulating layer 160, the pixel defining layer PDL, and the organic layer OL, which are arranged on the shielding pattern SHP, through a laser drilling process so that a portion of the second electrode CE may contact the shielding pattern SHP.

A pixel defining structure PDS arranged on the circuit layer DP-CL includes the pixel defining layer PDL and the step pattern SP arranged on the pixel defining layer PDL. As illustrated in FIGS. 9A and 9B, the step pattern SP may include the first step pattern SP1, the second step pattern SP2, and the third step pattern SP3, and may have a “valley pattern” having a shape recessed from an upper surface of the pixel defining layer PDL in the third direction DR3 that is a thickness direction. The step pattern SP may be arranged overlapping the shielding pattern SHP in a plan view.

The upper insulating layer TFL may be arranged on the light-emitting element layer DP-ED to protect the light-emitting element layer DP-ED from moisture, oxygen, and foreign matter such as dust particles. The upper insulating layer TFL may include the above-mentioned capping layer and encapsulation layer.

The input sensing unit ISU may be directly arranged on the upper insulating layer TFL, and may be formed on the upper insulating layer TFL through a continuous process. The input sensing unit ISU may include a plurality of sensing insulating layers TIL0, TIL1, TIL2, and TIL3 and a plurality of sensing conductive layers TCL1 and TCL2.

A sensing base layer TIL0 may be directly arranged on the upper insulating layer TFL. The sensing base layer TIL0 may be an inorganic layer including at least one of silicon nitride, silicon oxynitride, or silicon oxide. Alternatively, the sensing base layer TIL0 may be an organic layer including epoxy resin, acryl resin, or imide-based resin. The sensing base layer TIL0 may have a single-layer structure, or may have a multi-layer structure laminated along the third direction DR3. Meanwhile, the sensing base layer TIL0 may not be provided.

A first sensing insulating layer TIL1 and a second sensing insulating layer TIL2 may be arranged on the sensing base layer TIL0, and may be an inorganic layer including at least one of silicon nitride, silicon oxynitride, or silicon oxide. The first sensing insulating layer TIL1 and the second sensing insulating layer TIL2 may provide base surfaces on which a first sensing conductive layer TCL1 and a second sensing conductive layer TCL2 are arranged respectively.

The first sensing conductive layer TCL1 and the second sensing conductive layer TCL2 each may have a single-layer structure, or may have a multi-layer structure laminated along the third direction DR3. The first sensing conductive layer TCL1 and the second sensing conductive layer TCL2 may include conductive lines that define a mesh-shaped sensing electrode. The conductive lines may overlap the pixel defining layer PDL. Meanwhile, the first sensing conductive layer TCL1 and the second sensing conductive layer TCL2 may be included in the above-mentioned sensing pattern TCP. According to some embodiments, a portion of the sensing pattern TCP may overlap the shielding pattern SHP in a plan view. A portion of the first sensing conductive layer TCL1 and the second sensing conductive layer TCL2 may be electrically connected through a sensing contact hole T-C.

A conductive layer having a single-layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), or indium zinc tin oxide (IZTO). In addition, the transparent conductive layer may include a conductive polymer such as PEDOT, metal nanowire, graphene, or the like.

A conductive layer having a multi-layer structure may include sequentially stacked metal layers. The metal layers may have, for example, a triple-layer structure of titanium/aluminum/titanium. The conductive layer having a multi-layer structure may include at least one metal layer and at least one transparent conductive layer.

A third sensing insulating layer TIL3 may be arranged on the first sensing conductive layer TCL1 and the second sensing conductive layer TCL2. The third sensing insulating layer TIL3 may include an inorganic layer. The inorganic layer may include at least one of aluminum oxide, titanium oxide, silicon oxide, silicon nitride, silicon oxynitride, zirconium oxide, or hafnium oxide.

Alternatively, the third sensing insulating layer TIL3 may include an organic layer. The organic layer may include at least one of acrylic resin, methacrylic resin, polyisoprene, vinyl-based resin, epoxy-based resin, urethane-based resin, cellulosic resin, siloxane-based resin, polyimide-based resin, polyamide-based resin, or perylene-based resin.

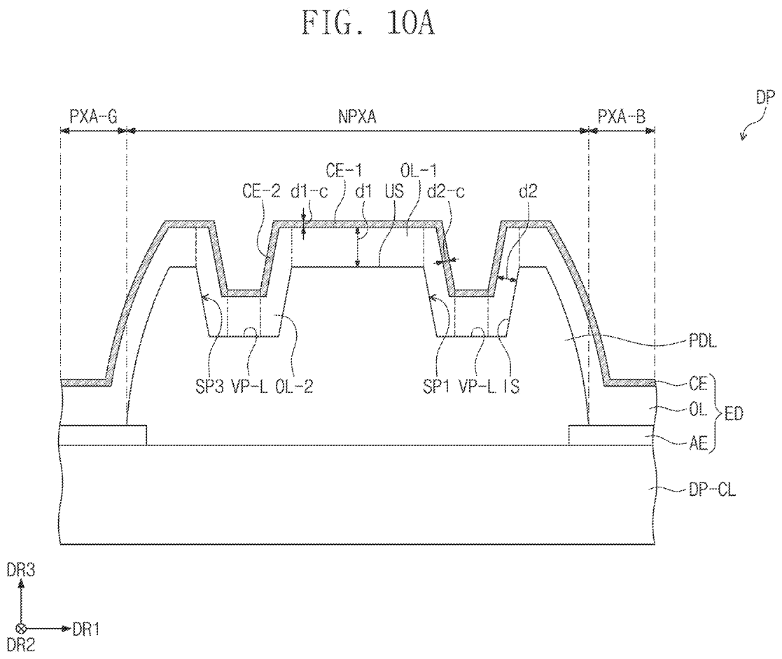

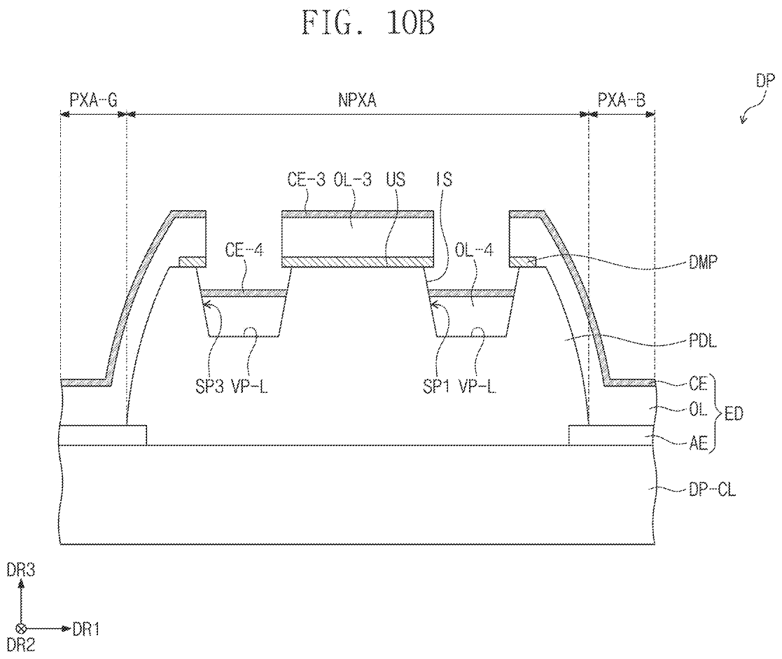

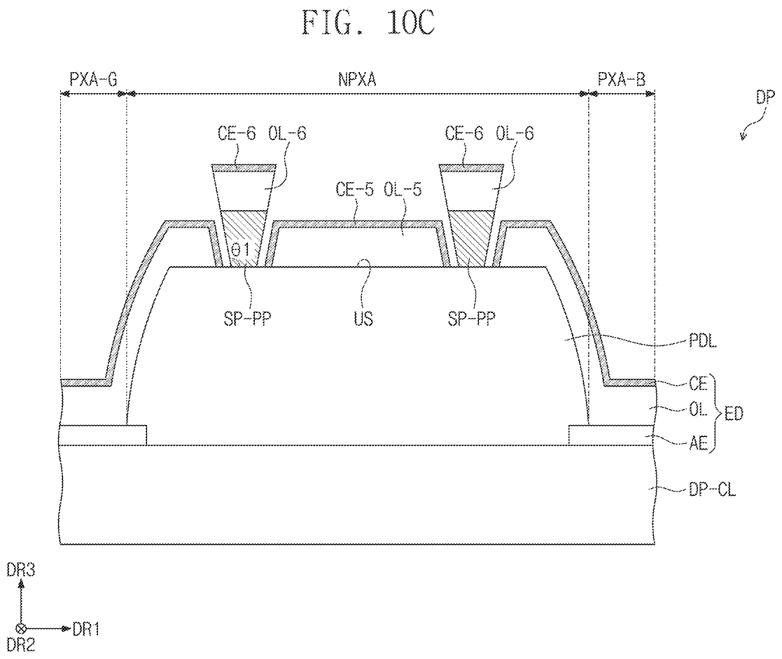

FIGS. 10A to 10C are enlarged cross-sectional views of a portion of a display panel according to some embodiments of the present disclosure. FIGS. 10A to 10C each illustrate an enlarged view according to some embodiments of the pixel defining structure PDS illustrated in FIGS. 9A and 9B.

Referring to FIGS. 9A and 10A, the pixel defining structure PDS arranged on the circuit layer DP-CL includes the pixel defining layer PDL and the step pattern SP arranged on the pixel defining layer PDL. The step pattern SP may include the first step pattern SP1, the second step pattern SP2, and the third step pattern SP3, and may have a “valley pattern” having a shape recessed from an upper surface of the pixel defining layer PDL in the third direction DR3 that is a thickness direction.

A recess depth to which the step pattern SP is recessed from an upper surface US of the pixel defining layer PDL may be about 100 nm to about 500 nm. When the recess depth is less than about 100 nm, thicknesses of the organic layer OL and the second electrode CE arranged on the pixel defining layer PDL decrease to a small degree, and the effect of preventing lateral leakage current may reduce. When the recess depth exceeds about 500 nm, the organic layer OL and the second electrode CE arranged on the pixel defining layer PDL may be damaged.

The step pattern SP having a recessed shape may include a lower surface VP-L and an inner side surface IS, and the inner side surface IS may be inclined at an angle (e.g., a set or predetermined angle) with respect to the lower surface VP-L. According to some embodiments, a taper angle at which the inner side surface IS is inclined from the lower surface VP-L may be about 70 degrees to about 90 degrees. When the taper angle is less than about 70 degrees, the thicknesses of the organic layer OL and the second electrode CE arranged on the pixel defining layer PDL decrease to a small degree, and the effect of preventing lateral leakage current may reduce. When the taper angle exceeds about 90 degrees, a side surface of the step pattern SP2 has an inversely tapered shape, and thus damage such as a crack may occur in the upper insulating layer TFL arranged on the step pattern SP2. A portion of the organic layer OL and the second electrode CE may be arranged in the step pattern SP.

According to some embodiments, the organic layer OL may include a first portion OL-1 arranged on the upper surface US of the pixel defining layer PDL and a second portion OL-2 arranged on the inner side surface IS of the step pattern SP. The second electrode CE may include a first electrode portion CE-1 arranged on the first portion OL-1 and a second electrode portion CE-2 arranged on the second portion OL-2. The first electrode portion CE-1 may be arranged on the upper surface US of the pixel defining layer PDL, and the second electrode portion CE-2 may be arranged on the inner side surface IS of the step pattern SP.

According to some embodiments, a thickness d2 of the second portion OL-2 may be smaller than a thickness d1 of the first portion OL-1. The thickness d2 of the second portion OL-2 arranged on the inner side surface IS may be about 10% to about 20% of the thickness d1 of the first portion OL-1. According to some embodiments, the thickness d1 of the first portion OL-1 may be about 200 nm to about 300 nm, and the thickness d2 of the second portion OL-2 may be about 30 nm to about 55 nm.

According to some embodiments, a thickness d2-c of the second electrode portion CE-2 may be smaller than a thickness d1-c of the first electrode portion CE-1. The thickness d2-c of the second electrode portion CE-2 may be about 10% to about 20% of the thickness d1-c of the first electrode portion CE-1. According to some embodiments, the thickness d1-c of the first electrode portion CE-1 may be about 90 Å to about 120 Å, and the thickness d2-c of the second electrode portion CE-2 may be about 10 Å to about 35 Å.

In a display device according to some embodiments, because the step pattern SP having a shape recessed in the thickness direction of the pixel defining layer PDL is formed, the second portion OL-2 of the organic layer OL and the second electrode portion CE-2 of the second electrode CE, arranged on the inner side surface IS of the step pattern SP, may be formed thin. Because thicknesses of the second portion OL-2 and the second electrode portion CE-2 decrease, the second portion OL-2 and the second electrode portion CE-2 have increased resistance, and thus current may be prevented from leaking to a portion in which the step pattern SP having increased resistance is formed.

Referring to FIGS. 9A and 10B, the display panel according to some embodiments may further include a dummy portion DMP arranged on the pixel defining layer PDL and partially overlapping the step pattern SP.

The dummy portion DMP may be arranged on the upper surface US of the pixel defining layer PDL, and a portion of the organic layer OL and the second electrode CE may be arranged on the dummy portion DMP.

According to some embodiments, the dummy portion DMP may be a residual portion of a mask used in a forming process of the step pattern SP. In the display panel according to some embodiments, an inorganic oxide film may be patterned so as to be used as a mask for forming the step pattern SP, and the dummy portion DMP may be a remaining portion, which was not etched, of the inorganic oxide film mask for forming the step pattern SP. According to some embodiments, the dummy portion DMP may include indium gallium zinc oxide (IGZO).

The dummy portion DMP may include a portion protruding to a length (e.g., a set or predetermined length) from a side surface of the step pattern SP. A protruding length to which the dummy portion DMP protrudes from the side surface of the step pattern SP may be, for example, about 0.05 micrometers to about 0.1 micrometers.

According to some embodiments, when a portion of the organic layer OL, arranged on the dummy portion DMP, is referred to as a third portion OL-3, and a portion of the organic layer OL, arranged in the step pattern SP, is referred to as a fourth portion OL-4, the third portion OL-3 and the fourth portion OL-4 may have disconnected shapes without being connected to each other. Furthermore, when a portion of the second electrode CE, arranged on the third portion OL-3, is referred to as a third electrode portion CE-3, and a portion of the second electrode CE, arranged on the fourth portion OL-4, is referred to as a fourth electrode portion CE-4, the third electrode portion CE-3 and the fourth electrode portion CE-4 may have disconnected shapes without being connected to each other. Meanwhile, a thickness of the third portion OL-3 and a thickness of the fourth portion OL-4 may be substantially the same. A thickness of the third electrode portion CE-3 and a thickness of the fourth electrode portion CE-4 may be substantially the same.

In the display panel according to some embodiments, because the dummy portion DMP protruding to a length (e.g., a set or predetermined length) from the side surface of the step pattern SP is included, the organic layer OL and the second electrode CE included in the display panel may have shapes disconnected by the step pattern SP. Accordingly, a current flowing between adjacent pixels in a direction of a plane defined by the first direction DR1 and the second direction DR2 may be efficiently prevented or reduced.

Referring to FIGS. 9A and 10C, in the display panel according to some embodiments, a step pattern SP-PP may have a protruding structure arranged on the upper surface US of the pixel defining layer PDL and having an inversely tapered shape from the upper surface US of the pixel defining layer PDL. The step pattern SP-PP may have a side surface arranged on the upper surface US of the pixel defining layer PDL and having a taper angle θ1 of at least 90 degrees with respect to the upper surface US of the pixel defining layer PDL. A portion of the organic layer OL and the second electrode CE may be arranged on the step pattern SP-PP.

According to some embodiments, when a portion of the organic layer OL, arranged on the upper surface US of the pixel defining layer PDL, is referred to as a fifth portion OL-5, and a portion of the organic layer OL, arranged on the step pattern SP-PP, is referred to as a sixth portion OL-6, the fifth portion OL-5 and the sixth portion OL-6 may have disconnected shapes without being connected to each other. Furthermore, when a portion of the second electrode CE, arranged on the fifth portion OL-5, is referred to as a fifth electrode portion CE-5, and a portion of the second electrode CE, arranged on the sixth portion OL-6, is referred to as a sixth electrode portion CE-6, the fifth electrode portion CE-5 and the sixth electrode portion CE-6 may have disconnected shapes without being connected to each other. Meanwhile, a thickness of at least a portion of the fifth portion OL-5 and a thickness of the sixth portion OL-6 may be substantially the same. A thickness of at least a portion of the fifth electrode portion CE-5 and a thickness of the sixth electrode portion CE-6 may be substantially the same.

In the display panel according to some embodiments, because the step pattern SP-PP protruding in an inversely tapered shape from the pixel defining layer PDL is included, the organic layer OL and the second electrode CE included in the display panel may have shapes disconnected by the step pattern SP-PP. Accordingly, a current flowing between adjacent pixels in a direction of a plane defined by the first direction DR1 and the second direction DR2 may be efficiently prevented or reduced.

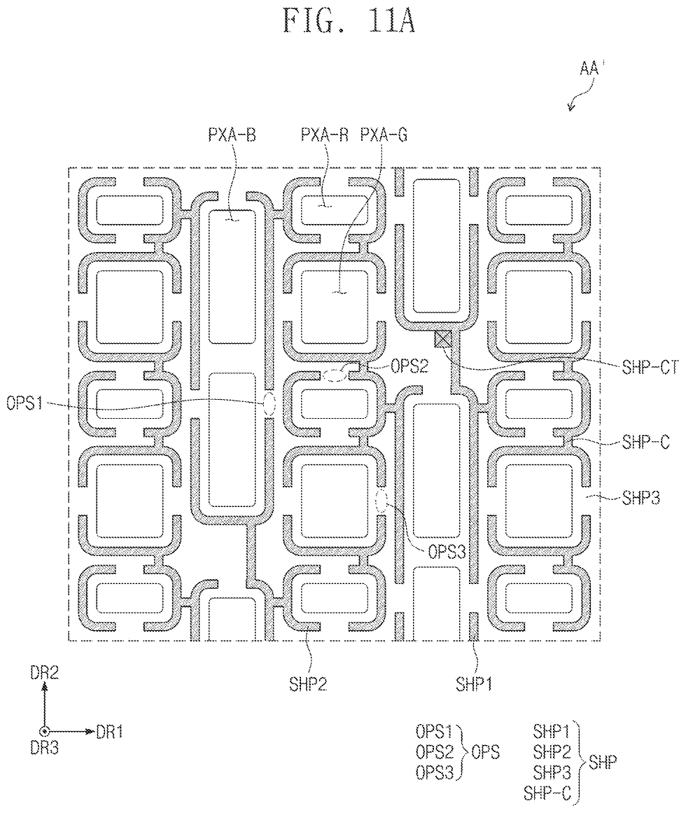

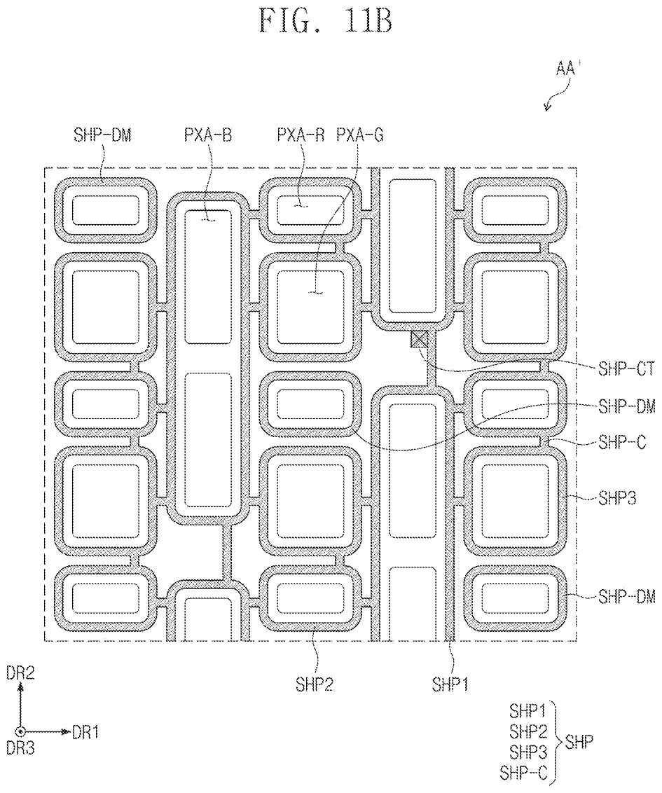

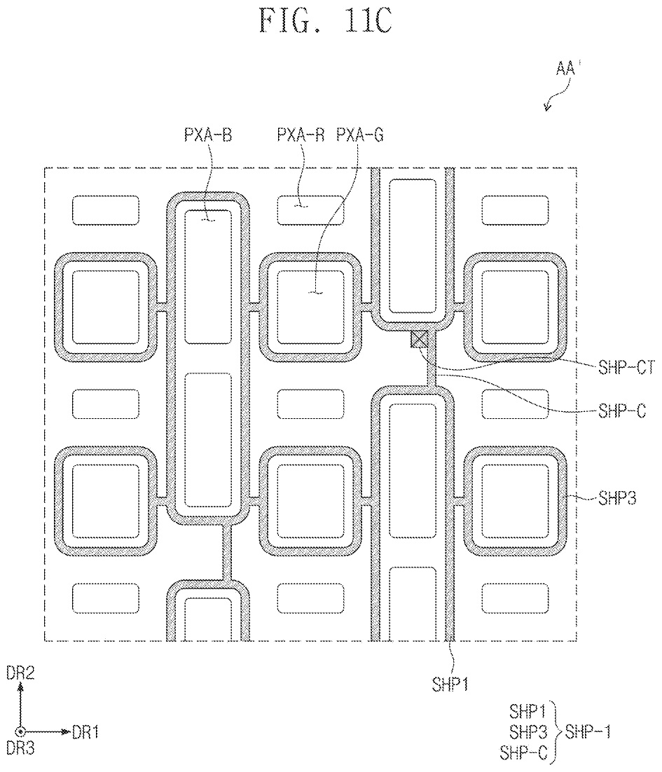

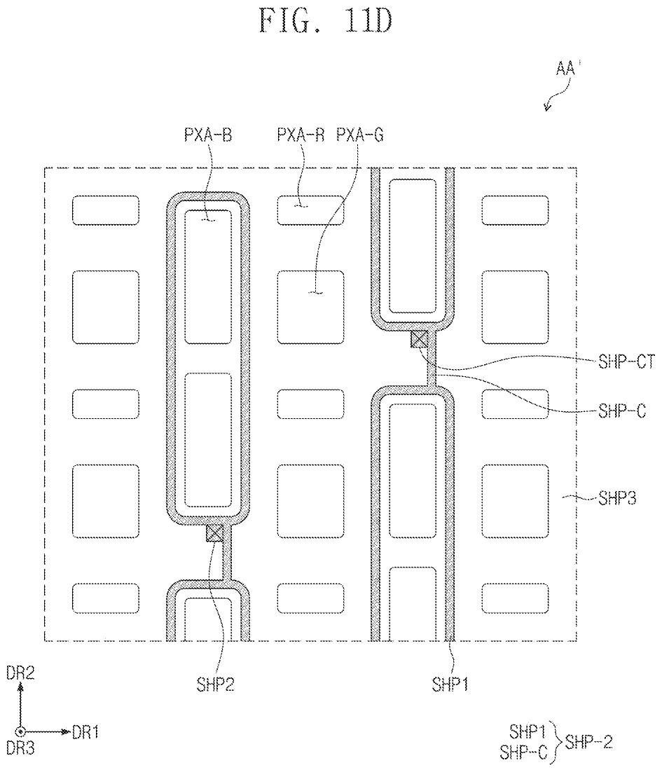

FIGS. 11A to 11D are enlarged plan views of a portion of a display module according to some embodiments of the present disclosure. FIGS. 11A to 11D illustrate arrangement of the plurality of pixel regions PXA and shapes of shielding patterns SHP arranged adjacent to the plurality of pixel regions PXA respectively, as in FIG. 8D, and illustrate a plan shape according to some embodiments different from the embodiments illustrated with respect to FIG. 8D.

Referring to FIGS. 8A, 8D, and 11A, the shielding pattern SHP may include the first shielding pattern SHP1 surrounding the first pixel region PXA-B, the second shielding pattern SHP2 surrounding the second pixel region PXA-R, and the third shielding pattern SHP3 surrounding the third pixel region PXA-G, and may include the connection shielding pattern SHP-C connecting the first shielding pattern SHP1, the second shielding pattern SHP2, and the third shielding pattern SHP3. The first shielding pattern SHP1, the second shielding pattern SHP2, and the third shielding pattern SHP3 surrounding the plurality of pixel regions PXA-B, PXA-R, and PXA-G respectively may be connected by the connection shielding pattern SHP-C and provided with the same voltage. The shielding pattern SHP may be supplied with a voltage through the shielding contact hole SHP-CT formed in an insulating layer in which the shielding pattern SHP is arranged among a plurality of insulating layers.

In the shielding pattern SHP, a sub open portion OPS may be defined, which overlaps the open portion OPP defined in the step pattern SP in a plan view. The first open portion OPP1 not surrounding a portion of the first pixel region PXA-B may be defined in the first step pattern SP1, and a first sub open portion OPS1 corresponding to the first open portion OPP1 may be defined in the first shielding pattern SHP1. The second open portion OPP2 not surrounding a portion of the second pixel region PXA-R may be defined in the second step pattern SP2, and a second sub open portion OPS2 corresponding to the second open portion OPP2 may be defined in the second shielding pattern SHP2. The third open portion OPP3 not surrounding a portion of the third pixel region PXA-G may be defined in the third step pattern SP3, and a third sub open portion OPS3 corresponding to the third open portion OPP3 may be defined in the third shielding pattern SHP3. In the shielding pattern SHP, because the sub open portion OPS overlapping the open portion OPP defined in the step pattern SP in a plan view is defined, the shielding pattern SHP excluding the connection shielding pattern SHP-C may have substantially the same shape as the step pattern SP in a plan view. However, embodiments of the present disclosure are not limited thereto, and a portion of the sub open portion OPS defined in the shielding pattern SHP may not be provided.

Referring to FIGS. 8D and 11B, the display panel according to some embodiments may further include a dummy shielding pattern SHP-DM. The dummy shielding pattern SHP-DM may be a floated conductive pattern without being connected to the shielding pattern SHP through the connection shielding pattern SHP-C. The dummy shielding pattern SHP-DM may surround a portion of the plurality of pixel regions PXA-B, PXA-R, and PXA-G. For example, as illustrated in FIG. 11B, the dummy shielding pattern SHP-DM may be arranged so as to surround a portion of the second pixel region PXA-R.

The dummy shielding pattern SHP-DM may be arranged on the same layer as the shielding pattern SHP. The dummy shielding pattern SHP-DM may include the same material and may be formed through the same process as the shielding pattern SHP. For example, as illustrated in FIG. 9A, the shielding pattern SHP may be arranged on the fifth insulating layer 150, and the dummy shielding pattern SHP-DM may also be arranged on the fifth insulating layer 150.

Referring to FIGS. 8A, 8B, 8D, and 11C, a shielding pattern SHP-1 may include the first shielding pattern SHP1 surrounding the first pixel region PXA-B and the third shielding pattern SHP3 surrounding the third pixel region PXA-G, and may include the connection shielding pattern SHP-C connecting the first shielding pattern SHP1 and the third shielding pattern SHP3. The first shielding pattern SHP1 and the third shielding pattern SHP3 surrounding the first pixel region PXA-B and the third pixel region PXA-G respectively may be connected by the connection shielding pattern SHP-C and provided with the same voltage. The shielding pattern SHP-1 may be supplied with a voltage through the shielding contact hole SHP-CT formed in an insulating layer in which the shielding pattern SHP-1 is arranged among a plurality of insulating layers.

Unlike the shielding pattern SHP illustrated in FIG. 8D, the shielding pattern SHP-1 according to some embodiments may not surround the second pixel region PXA-R. That is, the shielding pattern SHP-1 according to some embodiments may not include the second shielding pattern SHP2 surrounding the second pixel region PXA-R. Because the shielding pattern SHP-1 according to some embodiments does not include the second shielding pattern SHP2, the second step pattern SP2 arranged around the second pixel region PXA-R may not be covered with the shielding pattern SHP-1. The second step pattern SP2 may not overlap the shielding pattern SHP-1.

Referring to FIGS. 8A, 8B, 8D, and 11D, a shielding pattern SHP-2 may include the first shielding pattern SHP1 surrounding the first pixel region PXA-B, and may include the connection shielding pattern SHP-C connecting the first shielding pattern SHP1 provided in plurality. The first shielding patterns SHP1 surrounding the first pixel region PXA-B may be connected by the connection shielding pattern SHP-C and provided with the same voltage. The shielding pattern SHP-2 may be supplied with a voltage through the shielding contact hole SHP-CT formed in an insulating layer in which the shielding pattern SHP-2 is arranged among a plurality of insulating layers.

Unlike the shielding pattern SHP illustrated in FIG. 8D, the shielding pattern SHP-2 according to some embodiments may not surround the second pixel region PXA-R and the third pixel region PXA-G. That is, the shielding pattern SHP-2 according to some embodiments may not include the second shielding pattern SHP2 surrounding the second pixel region PXA-R and the third shielding pattern SHP3 surrounding the third pixel region PXA-G. Because the shielding pattern SHP-2 according to some embodiments does not include the second shielding pattern SHP2 and the third shielding pattern SHP3, the second step pattern SP2 arranged around the second pixel region PXA-R and the third step pattern SP3 arranged around the third pixel region PXA-G may not be covered with the shielding pattern SHP-2. The second step pattern SP2 and the third step pattern SP3 may not overlap the shielding pattern SHP-2.

As illustrated in FIGS. 11C and 11D, the shielding patterns SHP-1 and SHP-2 according to some embodiments may be arranged so as not to surround a portion of the plurality of pixel regions PXA-B, PXA-R, and PXA-G. The shielding patterns SHP-1 and SHP-2 according to some embodiments may be arranged so as to surround only a region in which a particular pixel having a high driving voltage is arranged among pixels arranged in each of the plurality of pixel regions PXA-B, PXA-R, and PXA-G. For example, as illustrated in FIG. 11D, the shielding pattern SHP-2 may include only the first shielding pattern SHP1 so as to surround the first pixel region PXA-B in which a blue pixel that emits the first light and has a highest driving voltage is arranged. Alternatively, as illustrated in FIG. 11C, the shielding pattern SHP-1 may include the first shielding pattern SHP1 and the third shielding pattern SHP3 so as to surround the first pixel region PXA-B in which a blue pixel that emits the first light and has a highest driving voltage is arranged and the third pixel region PXA-G in which a green pixel that emits the third light and has a second highest driving voltage is arranged.

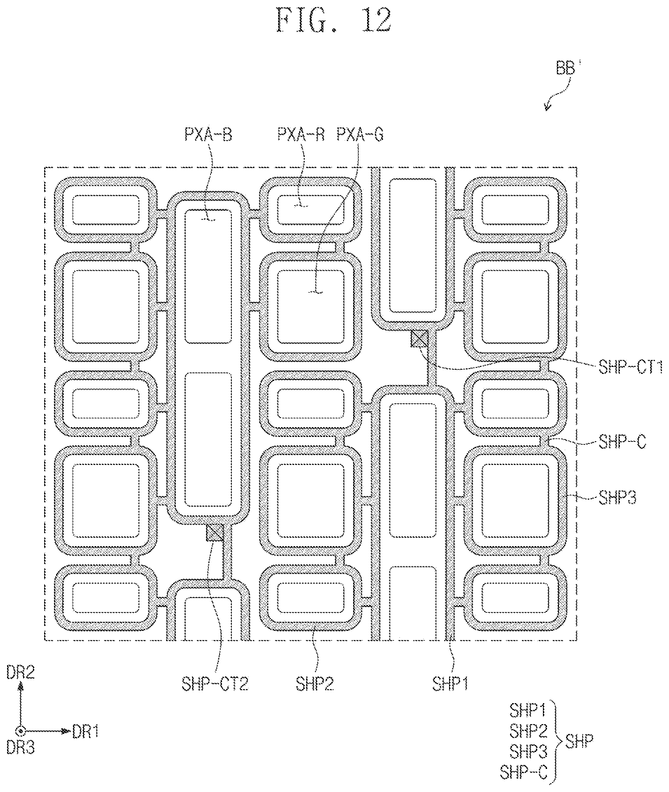

FIG. 12 is an enlarged plan view of a display module according to some embodiments of the present disclosure. FIG. 12 illustrates arrangement of the plurality of pixel regions PXA and shapes of shielding patterns SHP arranged adjacent to the plurality of pixel regions PXA respectively, in the region BB′ illustrated in FIG. 2.

The region AA′ and the region BB′ respectively illustrated in FIGS. 8D and 12 may have substantially the same area size. The region AA′ may have a first unit area size, the region BB′ may have a second unit area size, and the first unit area size and the second unit area size may be substantially the same. The number of the plurality of pixel regions PXA-B, PXA-R, and PXA-G included in the region AA′ and the number of the plurality of pixel regions PXA-B, PXA-R, and PXA-G included in the region BB′ may be the same. An arrangement of the plurality of pixel regions PXA-B, PXA-R, and PXA-G included in the region AA′ and an arrangement of the plurality of pixel regions PXA-B, PXA-R, and PXA-G included in the region BB′ may be the same. Meanwhile, the region AA′ may be referred to as a “first region”, and the region BB′ may be referred to as a “second region”.

When comparing FIGS. 8D and 12, the numbers of the shielding contact holes SHP-CT, SHP-CT1, and SHP-CT2 defined in the region AA′ and the region BB′ having the same unit area size may be different. As illustrated in FIGS. 8D and 12, one shielding contact hole SHP-CT may be defined in the region AA′, but two shielding contact holes SHP-CT1 and SHP-CT2 may be defined in the region BB′. That is, in the display module according to some embodiments of the present disclosure, two regions having the same area size may have different numbers of the shielding contact holes SHP-CT, SHP-CT1, and SHP-CT2. In the display module according to some embodiments, each region may be provided with different density of the shielding contact holes SHP-CT, SHP-CT1, and SHP-CT2. In the display module according to some embodiments of the present disclosure, because the density and number of shielding contact holes are differently adjusted in each region, voltage may be provided to the shielding pattern SHP in accordance with a condition for each region.

Meanwhile, unlike the illustration of FIG. 12, the region BB′ may be provided with only one shielding contact hole like the region AA′ illustrated in FIG. 8D. In the display module according to some embodiments, the density of shielding contact holes may be equally provided for each region.

In a display device according to some embodiments of the present disclosure and an electronic device including the same, a lateral leakage current may be prevented or reduced by a step pattern defined between adjacent pixels, and a shielding pattern, which overlaps the step pattern and to which a voltage (e.g., a set or predetermined voltage) is applied, may be provided. Therefore, a driving signal generated in a display panel may be prevented from being transferred to a sensing pattern of an input sensing unit while efficiently blocking the lateral leakage current, thus preventing or reducing deterioration of the sensitivity of the input sensing unit.

Although the embodiments of the present invention have been described, it is understood that the present invention should not be limited to these embodiments but various changes and modifications can be made by one ordinary skilled in the art within the spirit and scope of the present invention as hereinafter claimed, and their equivalents.

What is claimed is:

1. A display device comprising:
a base layer having a plurality of pixel regions including:
a first pixel region;
a second pixel region adjacent to the first pixel region; and
a non-pixel region surrounding the plurality of pixel regions;
a circuit layer on the base layer and including a plurality of insulating layers and a plurality of conductive patterns;
a light-emitting element layer on the circuit layer; and
an input sensing unit on the light-emitting element layer and including a sensing pattern overlapping the non-pixel region,
wherein the light-emitting element layer comprises:
a pixel defining structure overlapping the non-pixel region and having a plurality of pixel openings corresponding to the plurality of pixel regions respectively; and
a plurality of light-emitting elements at least partially in the plurality of pixel openings,
wherein the pixel defining structure includes a step pattern overlapping the non-pixel region and surrounding a portion of each of the plurality of pixel regions, and
the plurality of conductive patterns include a shielding pattern on at least one of the plurality of insulating layers and overlapping at least a portion of the step pattern in a plan view, at least a portion of the shielding pattern being configured to have a voltage applied thereto.

2. The display device of claim 1, wherein a light-emitting element from among the light-emitting elements comprises:
a first electrode on the circuit layer;
an organic layer on the first electrode and the pixel defining structure and including an emission layer; and
a second electrode on the organic layer,
wherein a portion of the organic layer and the second electrode is on the step pattern.

3. The display device of claim 2,
wherein the pixel defining structure further includes a pixel defining layer overlapping the non-pixel region,
the step pattern has a shape recessed from an upper surface of the pixel defining layer in a thickness direction of the pixel defining layer, and
the step pattern includes:
a lower surface that is parallel with the upper surface of the pixel defining layer; and
an inner side surface connecting the lower surface and the upper surface of the pixel defining layer.

4. The display device of claim 3, wherein the organic layer comprises:
a first portion arranged on the upper surface of the pixel defining layer; and
a second portion arranged on the inner side surface of the step pattern,
wherein a thickness of the second portion is smaller than a thickness of the first portion.

5. The display device of claim 3, wherein the second electrode comprises:
a first electrode portion on the upper surface of the pixel defining layer; and
a second electrode portion on the inner side surface of the step pattern,
wherein a thickness of the second electrode portion is smaller than a thickness of the first electrode portion.

6. The display device of claim 3,
wherein the pixel defining structure further includes a dummy portion on the pixel defining layer and partially overlapping the step pattern in the plan view, and
the organic layer includes:
a third portion on the dummy portion; and
a fourth portion on the lower surface of the step pattern,
wherein the third portion and the fourth portion are not connected.

7. The display device of claim 2,
wherein the pixel defining structure further includes a pixel defining layer overlapping the non-pixel region, and
the step pattern includes a side surface on the pixel defining layer and having an inversely tapered shape from an upper surface of the pixel defining layer.

8. The display device of claim 7, wherein the organic layer comprises:
a fifth portion on the pixel defining layer; and
a sixth portion on the step pattern,
wherein the fifth portion and the sixth portion are not connected.

9. The display device of claim 2,
wherein the first electrode is applied with a first power supply voltage, and
the shielding pattern is applied with a second power supply voltage different from the first power supply voltage.

10. The display device of claim 2, wherein the organic layer comprises:
a first light-emitting stack on the first electrode and the pixel defining structure and including a first emission layer;
a first charge generation layer on the first light-emitting stack; and
a second light-emitting stack between the first charge generation layer and the second electrode and including a second emission layer.

11. The display device of claim 1,
wherein the step pattern comprises:
a first step pattern surrounding a portion of the first pixel region; and
a second step pattern surrounding a portion of the second pixel region,
wherein when a portion in which the first step pattern does not surround the first pixel region is defined as a first open portion, and a portion in which the second step pattern does not surround the second pixel region is defined as a second open portion, the first open portion and the second open portion do not face each other.

12. The display device of claim 11, wherein the shielding pattern overlaps each of the first open portion and the second open portion of the step pattern in the plan view.

13. The display device of claim 11, wherein the shielding pattern comprises:
a first shielding pattern overlapping the first step pattern in the plan view; and
a second shielding pattern overlapping the second step pattern in the plan view,
wherein a first sub open portion corresponding to the first open portion is defined in the first shielding pattern, and a second sub open portion corresponding to the second open portion is defined in the second shielding pattern.

14. The display device of claim 11, wherein the circuit layer further includes a dummy shielding pattern in a same layer as the shielding pattern, spaced apart from the shielding pattern, and surrounding any one of the plurality of pixel regions.

15. The display device of claim 11, wherein the shielding pattern overlaps the first step pattern and does not overlap the second step pattern in the plan view.

16. The display device of claim 1,
wherein the circuit layer further includes a signal line electrically connected to a light-emitting element from among the light-emitting elements, and
the plurality of insulating layers include:
a first base insulating layer in which the signal line is arranged; and
a second base insulating layer on the first base insulating layer and in which the shielding pattern is arranged.

17. The display device of claim 1,
wherein the circuit layer further includes a signal line electrically connected to a light-emitting element from among the light-emitting elements, and
the signal line and the shielding pattern are on a same layer among the plurality of insulating layers.

18. The display device of claim 1,
wherein the plurality of pixel regions further include a third pixel region adjacent to the second pixel region,
the first pixel region is configured to display a first light having a first wavelength,
the second pixel region is configured to display a second light having a second wavelength different from the first wavelength, and
the third pixel region is configured to display a third light having a third wavelength different from the first wavelength and the second wavelength.

19. The display device of claim 1,
wherein the circuit layer further includes an active voltage line overlapping a portion of the plurality of pixel regions in the plan view, and
the shielding pattern is electrically connected to the active voltage line through a shielding contact hole defined in at least one of the plurality of insulating layers.

20. The display device of claim 19,
wherein a first region having a first unit area size and a second region having a second unit area size that is equal to the first unit area size and spaced apart from the first region are defined in the base layer, and
a number of shielding contact holes defined in the first region and a number of shielding contact holes defined in the second region are different from each other.

21. The display device of claim 1, wherein the sensing pattern overlaps at least a portion of the shielding pattern in the plan view.

22. A display device comprising:
a base layer having a plurality of pixel regions including:
a first pixel region;
a second pixel region adjacent to the first pixel region; and
a non-pixel region surrounding the plurality of pixel regions;
a plurality of insulating layers on the base layer;
a shielding pattern on the plurality of insulating layers and overlapping the non-pixel region, at least a portion of the shielding pattern being configured to have a voltage applied thereto;
a pixel defining structure overlapping the non-pixel region and having a plurality of pixel openings corresponding to the plurality of pixel regions respectively; and
a light-emitting element on the plurality of insulating layers and including an organic layer and an upper electrode on the organic layer,
wherein the pixel defining structure includes a step pattern overlapping the non-pixel region and surrounding a portion of each of the plurality of pixel regions,
a portion of the organic layer and the upper electrode is on the step pattern, and
the step pattern overlaps at least a portion of the shielding pattern in a plan view.

23. An electronic device comprising:
a display module having a plurality of pixel regions including:
a first pixel region configured to display a first light having a first wavelength;
a second pixel region adjacent to the first pixel region and configured to display a second light having a second wavelength different from the first wavelength; and
a non-pixel region surrounding the plurality of pixel regions;
a window on the display module; and
an external case under the display module,
wherein the display module comprises:
a base layer having a plurality of pixel regions including:
a first pixel region;
a second pixel region adjacent to the first pixel region; and
a non-pixel region surrounding the plurality of pixel regions;
a circuit layer on the base layer and including a plurality of insulating layers and a plurality of conductive patterns;
a light-emitting element layer on the circuit layer; and
an input sensing unit on the light-emitting element layer and including a sensing pattern overlapping the non-pixel region,
wherein the light-emitting element layer comprises:
a pixel defining structure overlapping the non-pixel region and having pixel openings corresponding to the plurality of pixel regions respectively; and
light-emitting elements at least partially in the pixel openings,
wherein the pixel defining structure includes a step pattern overlapping the non-pixel region and surrounding a portion of each of the plurality of pixel regions, and
the plurality of conductive patterns include a shielding pattern overlapping the step pattern in a plan view, at least a portion of the shielding pattern being configured to have a voltage applied thereto.
